(19) United States
(12) Patent Application Publication
(10) Pub. No.: US 2025/0299967 A1
(43) Pub. Date: Sep. 25, 2025

(54) METHOD OF MANUFACTURING SEMICONDUCTOR DEVICE AND SEMICONDUCTOR DEVICES PRODUCED BY SUCH METHODS

(71) Applicant: Samsung Electronics Co., Ltd., Suwon-si (KR)

(72) Inventors: Toshihiko Iwao, Suwon-si (KR); Songyun Kang, Suwon-si (KR)

(21) Appl. No.: 18/822,541

(22) Filed: Sep. 3, 2024

(30) Foreign Application Priority Data
Mar. 20, 2024 (KR) 10-2024-0038308

(51) Int. Cl. H01L 21/3205; C23C 16/14; C23C 16/44; C23C 16/50; H01L 21/285

(52) U.S. Cl. CPC H01L 21/32051; C23C 16/14; C23C 16/4408; C23C 16/50; H01L 21/28506

(57) ABSTRACT

A method of manufacturing a semiconductor device is provided, which includes preparing a substrate, supplying metal-containing precursors onto the substrate to form a substrate having metal containing precursors thereon, supplying hydrogen gas onto the substrate having metal-containing precursors thereon, and supplying a reducing agent onto the substrate having metal-containing precursors thereon, wherein the supplying of the reducing agent and the supplying of the hydrogen gas are simultaneously or sequentially performed, and wherein the metal-containing precursors include molybdenum dichloride dioxide (MoO₂Cl₂), and the reducing agent includes a hydrogen halide. Also included are semiconductor devices made by the present methods.

### CROSS-REFERENCE TO RELATED APPLICATION

This U.S. non-provisional application is based on and claims priority under 35 U.S.C. § 119 to Korean Patent Application No. 10-2024-0038308, filed on Mar. 20, 2024, in the Korean Intellectual Property Office, the disclosure of which is incorporated by reference herein in its entirety.

### BACKGROUND

The inventive concept relates to methods of manufacturing a semiconductor device and semiconductor devices produced by such methods.

Along with demands in various industry fields, the sizes of semiconductor devices have been gradually reduced and the geometric structures of semiconductor devices have been gradually complicated. Accordingly, a lot of problems related to deposition have occurred. In particular, when depositing a metal-containing layer by using chemical vapor deposition (CVD) or atomic layer deposition (ALD), a deposition speed may largely influence a production amount of semiconductor devices. In addition, oxygen impurities included in a metal-containing layer may influence the electrical characteristics of the metal-containing layer, thereby exerting an influence to the electrical characteristics and reliability of a semiconductor device.

### SUMMARY

The inventive concept provides a speed-improved method of manufacturing a semiconductor device.

The inventive concept also provides a method of manufacturing a semiconductor device with improved electrical characteristics.

In addition, the problems to be solved by the technical idea of the inventive concept are not limited to the problems mentioned above, and other problems could be clearly understood by those of ordinary skill in the art from the description herein.

According to an aspect of the inventive concept, there is provided a method of manufacturing a semiconductor device, the method including preparing a substrate, supplying metal-containing precursors onto the substrate to form a substrate having metal-containing precursors thereon, supplying hydrogen gas onto the substrate having metal-containing precursors thereon, and supplying a reducing agent onto the substrate having metal-containing precursors thereon, wherein the supplying of the reducing agent and the supplying of the hydrogen gas are simultaneously or sequentially performed, wherein the metal-containing precursors include molybdenum dichloride dioxide (MoO₂Cl₂), and wherein the reducing agent includes a hydrogen halide.

According to another aspect of the inventive concept, there is provided a method of manufacturing a semiconductor device, the method including forming a mold structure on a substrate, the mold structure including sacrificial layers and interlayer insulating layers alternately stacked one on another, forming vertical channel structures penetrating the mold structure, forming trenches spaced apart from the vertical channel structures in a horizontal direction and penetrating the mold structure, selectively removing the sacrificial layers through the trenches, forming gate electrodes in spaces from which the sacrificial layers have been removed, and forming an isolation structure filling the trenches, wherein the forming of the gate electrodes includes supplying metal-containing precursors onto the substrate to form a substrate having metal-containing precursors thereon, supplying hydrogen gas onto the substrate having metal-containing precursors thereon, and supplying a reducing agent onto the substrate having metal-containing precursors thereon, wherein the supplying of the reducing agent and the supplying of the hydrogen gas are simultaneously or sequentially performed, the metal-containing precursors include MoO₂Cl₂, and the reducing agent includes a hydrogen halide.

According to another aspect of the inventive concept, there is provided a method of manufacturing a semiconductor device, the method including supplying metal-containing precursors onto a substrate, the metal-containing precursors including MoO₂Cl₂, supplying first purge gas onto the substrate to which the metal-containing precursors have been supplied, the first purge gas including a first inert gas, simultaneously or sequentially supplying hydrogen gas and a reducing agent onto the substrate to which the metal-containing precursors have been supplied, the reducing agent including a hydrogen halide, supplying second purge gas onto the substrate to which the hydrogen gas and the reducing agent have been supplied, the second purge gas including inert gas, and checking whether a thickness of a metal-containing layer formed after supplying the second purge gas has reached a set target thickness, wherein, in the supplying of the hydrogen gas and the supplying of the reducing agent, the hydrogen gas and the reducing agent are supplied in a plasma state.

According to a further aspect of the inventive concept, provided are semiconductor devices manufactured by the present methods of manufacturing a semiconductor device.

### BRIEF DESCRIPTION OF THE DRAWINGS

Embodiments of the inventive concept will be more clearly understood from the following detailed description taken in conjunction with the accompanying drawings in which:

FIG. 1 is a flowchart schematically illustrating a method of manufacturing a semiconductor device, according to embodiments;

FIG. 2 is a flowchart schematically illustrating a method of manufacturing a semiconductor device, according to embodiments;

FIG. 3 is a flowchart schematically illustrating a method of manufacturing a semiconductor device, according to embodiments;

FIG. 4 is a flowchart schematically illustrating a method of manufacturing a semiconductor device, according to embodiments;

FIG. 5 is a flowchart schematically illustrating a method of manufacturing a semiconductor device, according to embodiments;

FIG. 6 is a flowchart schematically illustrating a method of manufacturing a semiconductor device, according to embodiments;

FIGS. 7 and 8 are graphs illustrating results of a comparative example and an experimental example, respectively, according to Vienna ab initio simulation package (VASP) calculation;

FIG. 9 is a top view illustrating a three-dimensional semiconductor memory device according to embodiments;

FIGS. 10A and 10B are cross-sectional views illustrating a three-dimensional semiconductor memory device according to embodiments and respectively correspond to cross-sections cut along lines I-I′ and II-II′ of FIG. 9;

FIG. 11A is a magnified view illustrating a portion of a three-dimensional semiconductor memory device according to embodiments and corresponds to a portion A of FIG. 10A;

FIG. 11B is a magnified view illustrating a portion of a three-dimensional semiconductor memory device according to embodiments and corresponds to a portion B of FIG. 10A;

FIG. 11C is a magnified view illustrating a portion of a three-dimensional semiconductor memory device according to embodiments and corresponds to a portion C of FIG. 10B; and

FIGS. 12A to 13B are cross-sectional views illustrating a method of manufacturing a three-dimensional semiconductor memory device, according to embodiments, and particularly, FIGS. 12A and 13A correspond to cross-sections cut along line I-I′ of FIG. 9, and FIGS. 12B and 13B correspond to cross-sections cut along line II-II′ of FIG. 9.

### DETAILED DESCRIPTION OF THE EMBODIMENTS

Hereinafter, embodiments are described in detail with reference to the accompanying drawings. The example embodiments herein are examples, and many implementations and variations are possible that do not require the details provided herein. It should also be emphasized that the disclosure provides details of alternative examples, but such listing of alternatives is not exhaustive. Like reference numerals in the drawings denote like elements, and thus their repetitive description will be omitted. The invention may, be embodied in many different forms and should not be construed as limited to the example embodiments set forth herein.

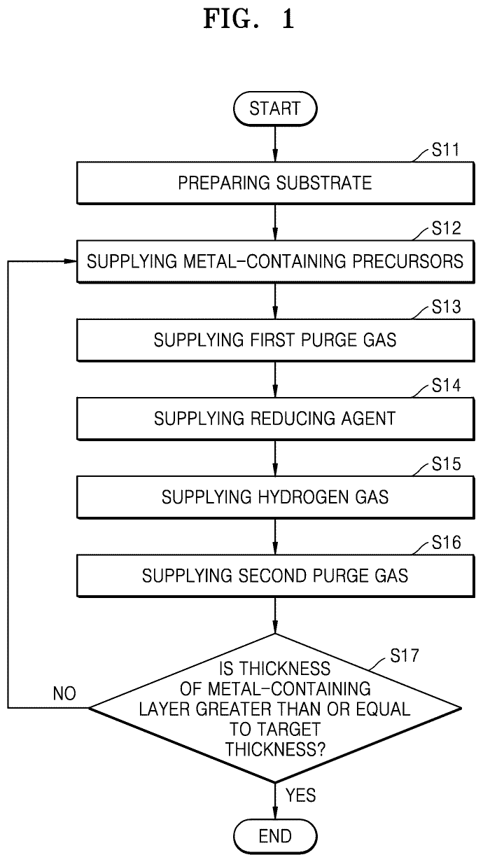

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed. As used herein, the term “and/or” includes any and all combinations of one or more of the associated listed items. FIG. 1 is a flowchart schematically illustrating a method of manufacturing a semiconductor device, according to embodiments.

Referring to FIG. 1, the method of manufacturing a semiconductor device, according to embodiments, may first include operation S11 of preparing a substrate.

The semiconductor device disclosed in the specification may include various semiconductor devices. For example, the semiconductor device may include a memory semiconductor device or a system semiconductor device.

The memory semiconductor device may include dynamic random access memory (DRAM), NAND flash, magnetic RAM (MRAM), parameter RAM (PRAM), resistive RAM (RRAM), ferroelectric RAM (FRAM), or the like. The system semiconductor device may include an application processor (AP), a complementary metal oxide semiconductor (CMOS) image sensor (CIS), a power management integrated circuit (PMIC), a display driver integrated circuit (DDIC), or the like. However, the semiconductor device is not limited to these examples and the invention may be applied to other devices normally used in the semiconductor field.

The substrate may include a semiconductor material. Particularly, the substrate may include for example, a material selected from the group consisting of silicon, germanium, silicon- germanium, a compound semiconductor, and the like. When the substrate includes a semiconductor material, the substrate may be in a monocrystalline, polycrystalline, or amorphous state.

However, a material which the substrate may include, is not limited thereto. For example, the substrate may include an insulating material, such as silicon oxide or silicon nitride. Alternatively, the substrate may correspond to a structure having a complicated geometric structure. When the substrate corresponds to a structure having a complicated geometric structure, the substrate may include two or more types of materials.

The substrate may be inside a reaction chamber. The reaction chamber may be a space in which the method of manufacturing a semiconductor device is performed. The reaction chamber may be a space in deposition equipment but is not limited thereto.

The reaction chamber may include a single type of reaction chamber, which accommodates only a single substrate, or a batch type of reaction chamber, or batch reactor, which accommodates a plurality of substrates. As another example, the reaction chamber may include a rotational batch type of reaction chamber. The types of the reaction chamber are not limited to these types and others may be included in the present invention.

Next, operation S12 of supplying metal-containing precursors may be performed. For example, the method of manufacturing a semiconductor device may include operation S12 of supplying the metal-containing precursors.

The metal-containing precursors may be supplied onto the substrate to form a metal-containing layer on the substrate. A metal in a metal-containing layer may include for example, at least one metal selected from the group consisting of molybdenum (Mo), tungsten (W), niobium (Nb), tantalum (Ta), chromium (Cr), and the like. For example, the metal in the metal-containing layer may include Mo, but is not limited thereto.

The metal-containing precursors may include, for example, molybdenum dichloride dioxide (MoO₂Cl₂), molybdenum tetrachloride monoxide (MoOCl₄), tungsten tetrachloride monoxide (WOCl₄), tungsten dichloride dioxide (WO₂Cl₂), niobium oxychloride (NbOCl₃), tantalum oxychloride (TaOCl₃), chromium dichloride dioxide (CrO₂Cl₂), or the like. For example, the metal-containing precursors may include MoO₂Cl₂ but are not limited thereto.

In operation S12 of supplying the metal-containing precursors, the metal-containing precursors may be adsorbed onto the substrate or the surface of the substrate, to create a substrate having metal-creating precursors thereon.

Alternatively, in other example embodiments, before operation S12 of supplying the metal-containing precursors, metal nitride may be previously deposited on the substrate to form a substrate having metal-creating nitride thereon. The metal nitride may include, for example, titanium nitride, tantalum nitride, or the like. In this embodiment, in operation S12 of supplying the metal-containing precursors, the metal-containing precursors may be adsorbed onto the surface of the metal nitride. The metal nitride may function as a seed layer on which the metal-containing layer may be grown. The metal nitride may function, for example, as the seed layer because the adhesion between the metal nitride and the metal-containing precursors is good.

Alternatively, before operation S12 of supplying the metal-containing precursors, the metal-containing layer may be deposited on the substrate. The metal-containing layer may include, for example, at least one element selected from Mo, W, Nb, Ta, and Cr. For example, the metal-containing layer may include Mo. In this embodiment, the metal-containing precursors may be adsorbed to the surface of the metal-containing layer.

In examples when the metal-containing layer includes Mo and the metal-containing precursors include MoO₂Cl₂, a process in which the metal-containing precursors react to the metal-containing layer may be represented by <Formula 1> below.

4Mo*(s)+MoO₂Cl₂(g)→2Mo—O(s)+Mo(b)+2MoCl(s) <Formula 1>

Hereinafter, as symbols belonging to a chemical formula, it is defined that “(s)” represents solid atoms (or molecules) arranged in the surface of the metal-containing layer, “(g)” represents gas atoms (or molecules), and “(b)” represents solid atoms (or molecules) arranged inside the metal-containing layer. In example embodiments for symbol “(b)”, it is defined that “(b)” represents solid atoms (or molecules) existing in a bulk form inside the metal-containing layer. Herein, the solid atoms (or molecules) represent atoms (or molecules) constituting the metal-containing layer.

<Formula 1> may be an example to particularly describe a mechanism in which the metal-containing layer reacts to the metal-containing precursors. Therefore, the mechanism in which the metal-containing layer reacts to the metal-containing precursors is not limited only to <Formula 1>. There may be various mechanisms in which the metal-containing layer reacts to the metal-containing precursors. However, for convenience of description, a reaction mechanism between the metal-containing layer and the metal-containing precursors is described with reference to <Formula 1>.

Referring to <Formula 1>, four Mo atoms (Mo*(s)) may react with one MoO₂Cl₂(g) molecule to produce two Mo—O(s) molecules, two MoCl(s) molecules, and one Mo(b) atom.

In <Formula 1>, Mo*(s) means a Mo atom to which no other element is bonded. The other element may include, for example, an oxygen element, a hydrogen element, a chloride element, or the like. Mo*(s) may be a Mo atom in the surface of the metal-containing layer. The metal-containing precursors may react to Mo*(s) in the surface of the metal-containing layer.

In <Formula 1>, Mo—O(s) means a state in which an oxygen atom is bonded to a Mo atom. Similarly to Mo*(s), Mo(b) means a Mo atom to which no other element is bonded. Mo(b) may result from the metal-containing precursors but is not limited thereto. MoCl(s) means a state in which a chloride atom is bonded to a Mo atom in a solid form.

In a product, Mo—O(s) may be in a state in which an oxygen impurity is bonded to a Mo atom. The oxygen impurity may increase the resistance of the metal-containing layer. Therefore, the oxygen impurity may deteriorate the electrical property of the metal-containing layer, and this may result in deterioration of the electrical property of the semiconductor device.

Similarly, the chloride atom in MoCl(s) may also exert a bad influence on the electrical property of the semiconductor device, and thus, removal of the chloride atom is needed. MoCl(s) means a state in which a chloride atom is bonded to a Mo atom.

Next, operation S13 of supplying first purge gas may be performed. For example, the method of manufacturing a semiconductor device may include operation S13 of supplying the first purge gas.

It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention.

The first purge gas may be supplied onto the substrate to which the metal-containing precursors have been supplied. The first purge gas may include, for example, a first inert gas, such as argon (Ar) or nitrogen (N₂). The first purge gas may remove surplus metal-containing precursors, which have not been adsorbed to the surface of the substrate, among the metal-containing precursors supplied in operation S12 of supplying the metal-containing precursors.

In operation S13 of supplying the first purge gas, the temperature of the substrate and the reaction chamber may not be limited to a particular range. In operation S13 of supplying the first purge gas, the pressure of the reaction chamber may not be limited to a particular range. In operation S13 of supplying the first purge gas, the flow rate of the first purge gas may not be limited to a particular range.

Next, operation S14 of supplying a reducing agent may be performed. For example, the method of manufacturing a semiconductor device may include operation S14 of supplying the reducing agent.

The reducing agent may be supplied onto the substrate to which the metal-containing precursors have been supplied. The reducing agent may remove for example, oxygen and hydrogen impurities included in the metal-containing precursors adsorbed to the substrate, metal-containing precursors adsorbed to a metal nitride layer, and/or the metal-containing precursors adsorbed to the metal-containing layer.

For example, the reducing agent may include a hydrogen halide. The hydrogen halide may be a molecule in which a halogen element is bonded to a hydrogen atom. The halogen element may be one of elements corresponding to group 17 in the periodic table. For example, the hydrogen halide may include at least one hydrogen halide selected from the group consisting of hydrogen fluoride (HF), hydrogen chloride (HCl), hydrogen bromide (HBr), hydrogen iodide (HI), and hydrogen astatide (HAt).

For example, when the metal-containing layer includes Mo and the metal-containing precursors include MoO₂Cl₂, the reducing agent may remove oxygen impurities generated through a reaction between the metal-containing layer and the metal-containing precursors. For example, the reducing agent may reduce the metal-containing precursors to the metal-containing layer.

In operation S14 of supplying the reducing agent, the temperature of the substrate and the reaction chamber may be about 300° C. to about 800° C. Particularly, the temperature of the substrate and the reaction chamber may be about 350° C. to about 750° C., about 400° C. to about 700° C., about 450° C. to about 650° C., about 500° C. to about 650° C., or about 500° C. to about 600° C. but is not limited thereto.

As used herein, the term “about” may reflect temperatures, pressures, flow rates, activation energy, enthalpy, and other features of the present invention that vary only a small amount and/or in a way that does not significantly alter examples that vary only in a small relative manner, and/or in a way that does not significantly alter the operation, functionality, or structure of certain elements. When describing the amounts herein using the term “about”, it should be understood that the amounts or ranges are included with a 0%-5% deviation around each amount and around each end of the ranges. It should also be understood that the exact amounts and exact ranges are also encompassed by the present disclosure.

In operation S14 of supplying the reducing agent, the gas pressure inside the reaction chamber may be about 0.1 Torr to about 100 Torr. Particularly, the gas pressure inside the reaction chamber may be about 10 Torr to about 90 Torr, about 20 Torr to about 90 Torr, about 30 Torr to about 90 Torr, about 30 Torr to about 80 Torr, about 40 Torr to about 80 Torr, or about 40 Torr to about 70 Torr, but is not limited thereto.

In operation S14 of supplying the reducing agent, the flow rate of the reducing agent may be about 100 sccm to about 100000 sccm. Particularly, the flow rate of the reducing agent may be about 200 sccm to about 90000 sccm, about 1000 sccm to about 80000 sccm, about 1000 sccm to about 70000 sccm, or about 20000 sccm to about 60000 sccm, but is not limited thereto.

Next, operation S15 of supplying hydrogen gas may be performed. For example, the method of manufacturing a semiconductor device may include operation S15 of supplying the hydrogen gas.

The hydrogen gas may be supplied onto the substrate to which the metal-containing precursors have been supplied. The hydrogen gas may be represented by a chemical formula of H₂. Similar to the reducing agent supplied in a previous operation, the hydrogen gas may remove oxygen impurities and chloride impurities generated through reaction between the metal-containing layer and the metal-containing precursors.

When the metal-containing layer includes Mo and the metal-containing precursors include MoO₂Cl₂, a process in which the hydrogen gas reacts to Mo—O(s) in <Formula 1> may be represented by <Formula 2> below.

Mo—O(s)+H₂(g)→Mo—OH(s)+H(g) <Formula 2>

<Formula 2> may be one example to particularly describe a mechanism in which hydrogen gas (H₂(g)) reacts to Mo with oxygen impurities (Mo—O(s)). Therefore, the mechanism in which H₂(g) reacts to Mo—O(s) is not limited only to <Formula 2>. There may be various mechanisms in which H₂(g) reacts to Mo—O(s), within the scope of the present invention. However, for convenience of description, the mechanism in which H₂(g) reacts to Mo—O(s) is described with reference to <Formula 2>.

Referring to <Formula 2>, H₂(g) may react to Mo—O(s) to produce Mo—OH(s) and H(g). H₂(g) may hydrate oxygen bonded to a Mo atom.

In addition, H₂(g) may react to Mo—OH(s) in <Formula 2>. A process in which H₂(g) reacts to Mo—OH(s) may be represented by <Formula 3> below.

Mo—O(s)+H₂(g)→Mo—OH(s)+H(g) <Formula 3>

<Formula 3> may be one example to particularly describe a mechanism in which hydrogen gas (H₂(g)) reacts to Mo with hydrate (—OH). Therefore, the mechanism in which H₂(g) reacts to Mo—OH(s) is not limited only to <Formula 3>. There may be various mechanisms in which H₂(g) reacts to Mo—OH(s), within the scope of the present invention. However, for convenience of description, the mechanism in which H₂(g) reacts to Mo—OH(s) is described with reference to <Formula 3>.

Referring to <Formula 3>, H₂(g) may react to Mo—OH(s) to produce Mo—OH(s) and H₂O(g). H₂(g) may reduce —OH.

In <Formula 3>, activation energy may be about 0.34 eV. <Formula 3> may represent an endothermic reaction. In <Formula 3>, the total enthalpy of products may be greater than the total enthalpy of reactants. In <Formula 3>, the enthalpy difference between the reactants and the products may be about 0.18 eV.

When the metal-containing layer includes Mo, the metal-containing precursors include MoO₂Cl₂, and the reducing agent includes hydrogen chloride (HCl), a process in which Mo—OH(s) in <Formula 2> reacts may be represented by <Formula 4> below.

Mo—OH(s)+HCl(g)→MoCl(s)+H₂O(g) <Formula 4>

<Formula 4> may be one example to particularly describe a mechanism in which HCl(g) reacts to Mo with —OH(Mo—OH(s)). Therefore, the mechanism in which HCl(g) reacts to Mo—OH(s) is not limited only to <Formula 4>. There may be various mechanisms in which HCl(g) reacts to Mo—OH(s) within the scope of the present invention. However, for convenience of description, the mechanism in which HCl(g) reacts to Mo—OH(s) is described with reference to <Formula 4>.

Referring to <Formula 4>, HCl(g) may react to Mo—OH(s) to produce MoCl(s) and H₂O(g).

In <Formula 4>, activation energy may be about 0 eV. For example, the activation energy of <Formula 4> may not exist. <Formula 4> may represent an endothermic reaction. In <Formula 4>, the total enthalpy of products may be less than the total enthalpy of reactants. In <Formula 4>, the enthalpy difference between the reactants and the products may be about 0.65 eV.

Operation S14 of supplying the reducing agent and operation S15 of supplying the hydrogen gas may be separately performed. For example, the reducing agent and the hydrogen gas may not be simultaneously supplied. In example embodiments, operation S14 of supplying the reducing agent and operation S15 of supplying the hydrogen gas may be sequentially performed. Therefore, a pipe through which the reducing agent is supplied in operation S14 of supplying the reducing agent may differ from a pipe through which the hydrogen gas is supplied in operation S15 of supplying the hydrogen gas. When the pipe through which the reducing agent is supplied differs from the pipe through which the hydrogen gas is supplied, it may be prevent that the reducing agent unnecessarily reacts to the hydrogen gas.

A process in which some of the products produced through <Formula 1> to <Formula 4> react may be represented by <Formula 5> below.

MoCl(s)+MoH(s)→2Mo*(s)+HCl(g) <Formula 5>

<Formula 5> may be one example to particularly describe a mechanism in which Mo with a chloride impurity (MoCl(s)) reacts to Mo with a hydrogen impurity (MoH(s)). Therefore, the mechanism in which MoCl(s) reacts to MoH(s) is not limited only to <Formula 5>. There may be various mechanisms in which MoCl(s) reacts to MoH(s), within the scope of the present invention. However, for convenience of description, the mechanism in which MoCl(s) reacts to MoH(s) is described with reference to <Formula 5>.

MoCl(s) may react to MoH(s) to produce two Mo atoms (Mo*(s)) without impurities and hydrogen chloride (HCl(g)). Mo atoms without impurities may be conformally formed on the surface of the metal-containing layer.

A reaction speed constant k indicating the characteristic of the reaction speed of a chemical reaction may be represented by <Formula 6> below.

k=A*e^{-Ea/RT} <Formula 6>

In <Formula 6>, A denotes a constant, Ea denotes activation energy, R denotes a gas constant, and T denotes an absolute temperature. Referring to <Formula 6>, as activation energy decreases, and as an absolute temperature increases, the speed of a chemical reaction may increase.

If operation S14 of supplying the reducing agent in the method of manufacturing a semiconductor device is omitted, the reaction of <Formula 4> may not occur. In this example, as in <Formula 3>, Mo—OH(s) may react to H₂(g) to produce MoH(s). In addition, as in <Formula 5>, MoH(s) may react to MoCl(s) produced in <Formula 1> to produce Mo*(s). In this example, the activation energy of <Formula 3> may be about 0.34 eV.

However, the method of manufacturing a semiconductor device, according to the present invention, may include operation S14 of supplying the reducing agent. In operation S14 of supplying the reducing agent, as in <Formula 4>, Mo—OH(s) may react to HCl(g) to produce MoH(s). In this embodiment, activation energy may be about 0 eV.

Therefore, in terms of activation energy, the speed of the chemical reaction of <Formula 3> may be much greater than the speed of the chemical reaction of <Formula 4>. Particularly, at 600° C., the reaction speed constant k in <Formula 4> may be maximum 719 times greater than the reaction speed constant k in <Formula 3>. For example, by the method of manufacturing a semiconductor device, according to the technical idea of the inventive concept, the deposition speed of the metal-containing layer may be dramatically improved.

If the deposition speed of the metal-containing layer is dramatically improved, the manufacturing time of the semiconductor device may be eventually reduced. This may improve a production amount of the semiconductor device per unit time, thereby eventually reducing a manufacturing cost of the semiconductor device.

In addition, the chemical reaction of <Formula 4> may be an exothermic reaction. Because the activation energy of the chemical reaction of <Formula 4> is about 0 eV and the chemical reaction of <Formula 4> is an exothermic reaction, compared to an example where the reducing agent is not supplied, it may be easier to remove oxygen impurities bonded to (or included in) the metal-containing layer. As described above, oxygen impurities may deteriorate the electrical property of the metal-containing layer, and this may also deteriorate the electrical characteristics of the semiconductor device. Therefore, by the method of manufacturing a semiconductor device, according to the technical idea of the inventive concept, the electrical characteristics of the metal-containing layer and the semiconductor device may be improved.

Next, operation S16 of supplying second purge gas may be performed. For example, the method of manufacturing a semiconductor device may include operation S16 of supplying the second purge gas.

The second purge gas may be supplied onto the substrate to which the hydrogen gas and the reducing agent have been supplied. The second purge gas may include, for example, a second inert gas, such as Ar or N₂. The second purge gas may remove surplus metal-containing precursors, which have not been adsorbed to the surface of the substrate, among the metal-containing precursors supplied in operation S12 of supplying the metal-containing precursors. The second purge gas may include the same element as the first purge gas or include a different element from that of the first purge gas.

In operation S16 of supplying the second purge gas, the temperature of the substrate and the reaction chamber may not be limited to a particular range. In operation S16 of supplying the second purge gas, the pressure of the reaction chamber may not be limited to a particular range. In operation S16 of supplying the second purge gas, the flow rate of the second purge gas may not be limited to a particular range.

Next, operation S17 of determining whether the thickness of the metal-containing layer is greater than or equal to a target thickness may be performed. For example, the method of manufacturing a semiconductor device may include operation S17 of determining whether the thickness of the metal-containing layer is greater than the target thickness.

After performing operation S12 of supplying the metal-containing precursors to operation S16 of supplying the second purge gas, operation S17 of determining whether the thickness of the metal-containing layer is greater than or equal to the target thickness may be performed. Herein, the target thickness may be about 50 Å. However, the target thickness is not limited to this value. The target thickness may have various ranges.

If the thickness of the metal-containing layer is greater than the target thickness (YES on FIG. 1), the method of manufacturing a semiconductor device ends. However, if the thickness of the metal-containing layer does not reach the target thickness (NO on FIG. 1), the method may proceed to operation S12 of supplying metal-containing precursors again. Operation S12 of supplying the metal-containing precursors to operation S16 of supplying the second purge gas constitute one cycle of the method of manufacturing a semiconductor device, and this cycle of the method of manufacturing a semiconductor device may be continuously repeated until the thickness of the metal-containing layer reaches the target thickness. By doing this, the thickness of the metal-containing layer may be precisely adjusted in the level of an atomic size to a pre-determined desired thickness.

Alternatively, after this cycle is performed a plurality of times, operation S17 of determining whether the thickness of the metal-containing layer is greater than or equal to the target thickness may be performed. This may differ from, after performing this cycle only once, performing operation S17 of determining whether the thickness of the metal-containing layer is greater than or equal to the target thickness. Because operation S17 of determining whether the thickness of the metal-containing layer is greater than or equal to the target thickness may take time and cost, in accordance with circumstances, this cycle of steps S12-S16 may be performed a plurality of times before performing operation S17 of determining whether the thickness of the metal-containing layer is greater than or equal to the target thickness may be performed. In this embodiment, the manufacturing time and cost of the semiconductor device may be reduced. For example, if it is known that a particular number of cycles will be required before the thickness approaches a desired target thickness, the method may include performing that number of cycles first, before determining whether the thickness of the metal-containing layer is greater than or equal to the target thickness.

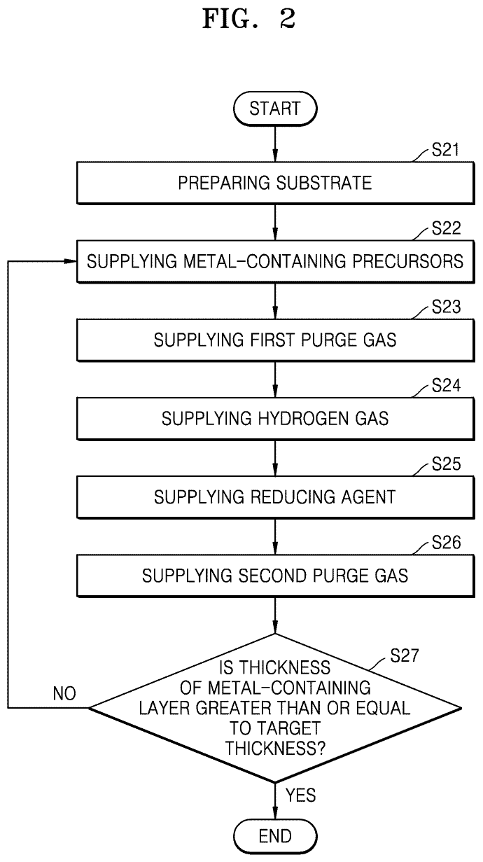

FIG. 2 is a flowchart schematically illustrating a method of manufacturing a semiconductor device, according to embodiments.

Referring to FIG. 2, the method of manufacturing a semiconductor device, according to embodiments, may include operation S21 of preparing a substrate, operation S22 of supplying metal-containing precursors, operation S23 of supplying first purge gas, operation S24 of supplying hydrogen gas, operation S25 of supplying a reducing agent, operation S26 of supplying second purge gas, and operation S27 of determining whether the thickness of a metal-containing layer is greater than or equal to a target thickness.

Operation S21 of preparing the substrate to operation S27 of determining whether the thickness of the metal-containing layer is greater than or equal to the target thickness may be sequentially performed. A description of operation S21 of preparing the substrate may be the same as the description, with reference to FIG. 1, of operation S11 of preparing the substrate.

A description of operation S22 of supplying the metal-containing precursors may be the same as the description, with reference to FIG. 1, of operation S12 of supplying the metal-containing precursors.

A description of operation S23 of supplying the first purge gas may be the same as the description, with reference to FIG. 1, of operation S13 of supplying the first purge gas.

A description of operation S24 of supplying the hydrogen gas may be almost the same as the description of operation S15, of FIG. 1, of supplying the hydrogen gas. However, the method of manufacturing a semiconductor device in FIG. 2 may differ from the method of manufacturing a semiconductor device in FIG. 1 in that operation S24 of supplying the hydrogen gas in the embodiments of FIG. 2 is performed earlier than operation S25 of supplying the reducing agent. For example, operation S24 is performed in the methods of FIG. 2 before supplying the reducing agent, rather than after.

A description of operation S25 of supplying the reducing agent may be almost the same as the description of operation S14 of FIG. 1 of supplying the reducing agent. However, the method of manufacturing a semiconductor device in FIG. 2 may differ from the method of manufacturing a semiconductor device in FIG. 1 in that operation S25 of supplying the reducing agent is performed later than operation S24 of supplying the hydrogen gas. For example, the method of manufacturing a semiconductor device in FIG. 2 may differ from the method of manufacturing a semiconductor device in FIG. 1 in an order of supplying the hydrogen gas and the reducing agent. In FIG. 2, the operation S25 is performed after supplying hydrogen gas.

A description of operation S26 of supplying the second purge gas may be the same as the description, with reference to FIG. 1, of operation S16 of supplying the second purge gas.

A description of operation S27 of determining whether the thickness of the metal-containing layer is greater than or equal to the target thickness may be the same as the description, with reference to FIG. 1, of operation S17 of determining whether the thickness of the metal-containing layer is greater than or equal to the target thickness. Similar to operation S17 of FIG. 1, operation S27 of determining whether the thickness of the metal-containing layer is greater than or equal to the target thickness may take time and cost. In accordance with circumstances, this cycle of steps S22-S26 may be performed a plurality of times before performing operation S27 of determining whether the thickness of the metal-containing layer is greater than or equal to the target thickness may be performed. In this embodiment, the manufacturing time and cost of the semiconductor device may be reduced. For example, if it is known that a particular number of cycles will be required before the thickness approaches a desired target thickness, the method may include performing that number of cycles first, before determining whether the thickness of the metal-containing layer is greater than or equal to the target thickness.

Referring to FIGS. 1 and 2, the reducing agent may be supplied earlier or later than the hydrogen gas. For example, an operation of supplying the reducing agent may be freely changed with respect to an operation of supplying the hydrogen gas. Therefore, the degree of process freedom of the method of manufacturing a semiconductor device may increase.

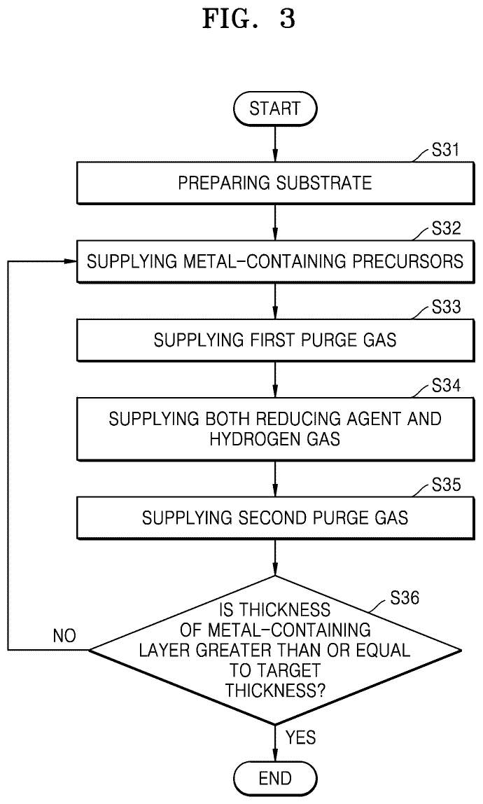

FIG. 3 is a flowchart schematically illustrating a method of manufacturing a semiconductor device, according to example embodiments.

Referring to FIG. 3, the method of manufacturing a semiconductor device, according to example embodiments, may include operation S31 of preparing a substrate, operation S32 of supplying metal-containing precursors, operation S33 of supplying first purge gas, operation S34 of supplying both a reducing agent and hydrogen gas, operation S35 of supplying second purge gas, and operation S36 of determining whether the thickness of a metal-containing layer is greater than or equal to a target thickness. As with other embodiments, operations S32-S35 (i.e. the operation steps prior to determining if the thickness of metal-containing layer is greater than or equal to target thickness) may be repeated multiple times before operation S36 is performed.

Operation S31 of preparing the substrate to operation S36 of determining whether the thickness of the metal-containing layer is greater than or equal to the target thickness may be sequentially performed. A description of operation S31 of preparing the substrate may be the same as the description, with reference to FIG. 1, of operation S11 of preparing the substrate.

A description of operation S32 of supplying the metal-containing precursors may be the same as the description, with reference to FIG. 1, of operation S12 of supplying the metal-containing precursors.

A description of operation S33 of supplying the first purge gas may be the same as the description, with reference to FIG. 1, of operation S13 of supplying the first purge gas.

A description of operation S34 of supplying both the reducing agent and the hydrogen gas may be similar to the description, with reference to FIG. 1, of operation S14 of supplying the reducing agent and operation S15 of supplying the hydrogen gas. For example, the reducing agent may include a hydrogen halide. For example, in operation S34 of supplying both the reducing agent and the hydrogen gas, the chemical reactions described with reference to <Formula 2> to <Formula 5> may occur.

However, the method of manufacturing a semiconductor device in FIG. 3 may differ from the methods of manufacturing a semiconductor in FIGS. 1 and 2 in that the hydrogen gas and the reducing agent are supplied simultaneously instead of individually.

As used herein, the term “simultaneously” means that the hydrogen as and the reducing agent may be supplied starting and ending at the same time as one another, or they may start and/or end at different times and have overlapping supply time. Both embodiments are encompassed by S34 supplying both reducing agent and hydrogen gas. As used herein, the term “sequentially”, is intended to mean that one step is completed before the next one ends. In different example embodiments, different steps may take place in a different order, but all orders are intended to be included, so long as one is completed before the next begins.

When the hydrogen gas and the reducing agent are simultaneously supplied, the manufacturing time of the semiconductor device may be dramatically reduced.

Referring to FIGS. 1 to 3, the reducing agent and the hydrogen gas may be individually or simultaneously supplied. In example embodiments, the reducing agent and the hydrogen gas may be simultaneously or sequentially supplied. For example, an operation of supplying the reducing agent may be freely changed with respect to an operation of supplying the hydrogen gas. Therefore, the degree of process freedom of the method of manufacturing a semiconductor device may increase.

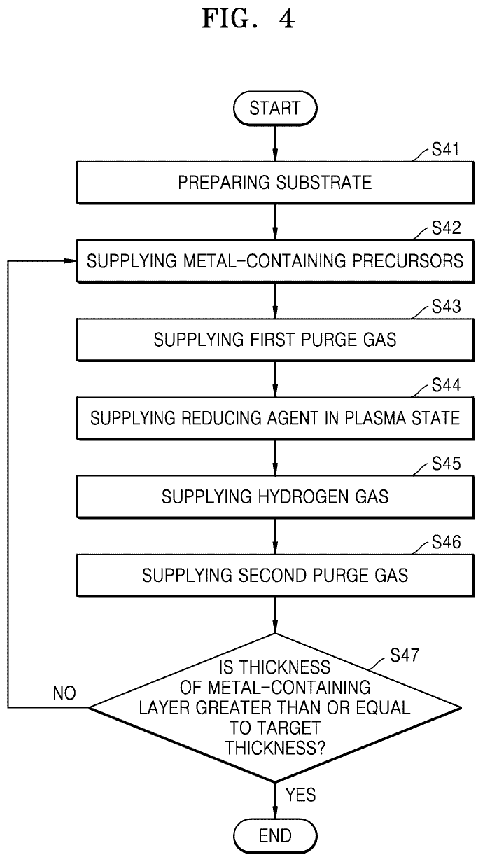

FIG. 4 is a flowchart schematically illustrating a method of manufacturing a semiconductor device, according to example embodiments.

Referring to FIG. 4, the method of manufacturing a semiconductor device, according to embodiments, may include operation S41 of preparing a substrate, operation S42 of supplying metal-containing precursors, operation S43 of supplying first purge gas, operation S44 of supplying a reducing agent in a plasma state, operation S45 of supplying hydrogen gas, operation S46 of supplying second purge gas, and operation S47 of determining whether the thickness of a metal-containing layer is greater than or equal to a target thickness.

Operation S41 of preparing the substrate to operation S47 of determining whether the thickness of the metal-containing layer is greater than or equal to the target thickness may be sequentially performed. A description of operation S41 of preparing the substrate may be the same as the description, with reference to FIG. 1, of operation S11 of preparing the substrate.

A description of operation S42 of supplying the metal-containing precursors may be the same as the description, with reference to FIG. 1, of operation S12 of supplying the metal-containing precursors.

A description of operation S43 of supplying the first purge gas may be the same as the description, with reference to FIG. 1, of operation S13 of supplying the first purge gas.

A description of operation S44 of supplying the reducing agent in the plasma state may be almost the same as the description, with reference to FIG. 1, of operation S14 of supplying the reducing agent. However, the method of manufacturing a semiconductor device in FIG. 4 may differ from the method of manufacturing a semiconductor device in FIG. 1 in that the reducing agent in the plasma state is supplied, as described further herein.

The reducing agent in the plasma state may be produced using, for example, a plasma manufacturing method, such as a direct current (DC) plasma manufacturing method or a radio frequency (RF) plasma manufacturing method, or other plasma manufacturing method known to those skilled in the art. The reducing agent in the plasma state may be produced for example, by arranging two electrodes in a reaction chamber, supplying the reducing agent to the reaction chamber, and then applying a DC current or an alternating current (AC) current to the two electrodes.

When the reducing agent includes a hydrogen halide, the reducing agent in the plasma state may include for example, a hydrogen radical and a halogen element radical. A radical existing in the plasma state may have high energy.

Therefore, when the reducing agent in the plasma state is supplied, the reaction of <Formula 4> described with reference to FIG. 1 may be more quickly performed. Therefore, by the method of manufacturing a semiconductor device, according to example embodiments, the deposition speed of the metal-containing layer may be dramatically improved.

A description of operation S45 of supplying the hydrogen gas may be the same as the description, with reference to FIG. 1, of operation S15 of supplying the hydrogen gas. However, in operation S45 of supplying the hydrogen gas, the hydrogen gas may also be supplied in the plasma state. Producing the hydrogen gas in the plasma state may use the same method as a method of producing the reducing agent in the plasma state.

A description of operation S46 of supplying the second purge gas may be the same as the description, with reference to FIG. 1, of operation S16 of supplying the second purge gas.

A description of operation S47 of determining whether the thickness of the metal-containing layer is greater than or equal to the target thickness may be the same as the description, with reference to FIG. 1, of operation S17 of determining whether the thickness of the metal-containing layer is greater than or equal to the target thickness. As with other embodiments, in non-limiting examples, operations S42-S46 may be repeated multiple times before operation S47 is performed.

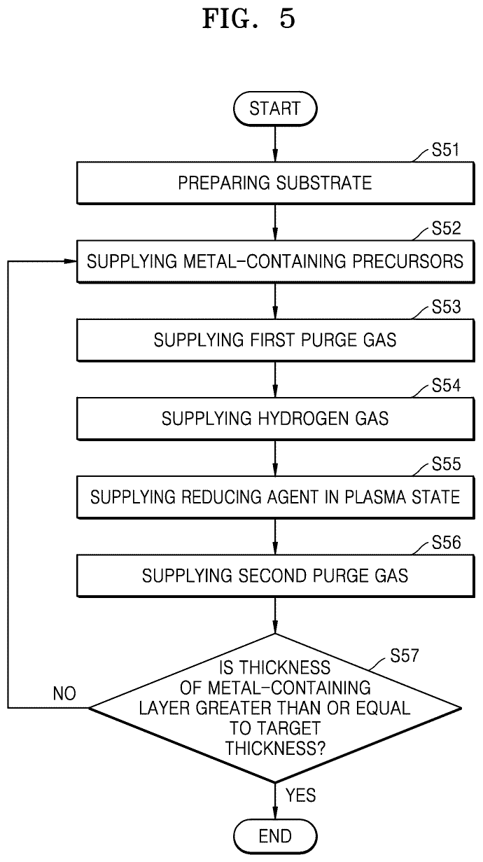

FIG. 5 is a flowchart schematically illustrating a method of manufacturing a semiconductor device, according to example embodiments.

Referring to FIG. 5, the method of manufacturing a semiconductor device, according to embodiments, may include operation S51 of preparing a substrate, operation S52 of supplying metal-containing precursors, operation S53 of supplying first purge gas, operation S54 of supplying hydrogen gas, operation S55 of supplying a reducing agent in the plasma state, operation S56 of supplying second purge gas, and operation S57 of determining whether the thickness of a metal-containing layer is greater than or equal to a target thickness.

The method of manufacturing a semiconductor device in FIG. 5 may be almost the same as the method of manufacturing a semiconductor device in FIG. 4. However, the method of manufacturing a semiconductor device in FIG. 5 may differ from the method of manufacturing a semiconductor device in FIG. 4 in that operation S55 of supplying the reducing agent in the plasma state is performed later than operation S54 of supplying the hydrogen gas. Like the description made with reference to FIG. 4, in operation S54 of supplying the hydrogen gas, the hydrogen gas may also be supplied in the plasma state.

As with other embodiments, in non-limiting examples, operations S52-S56 may be repeated multiple times before operation S57 is performed.

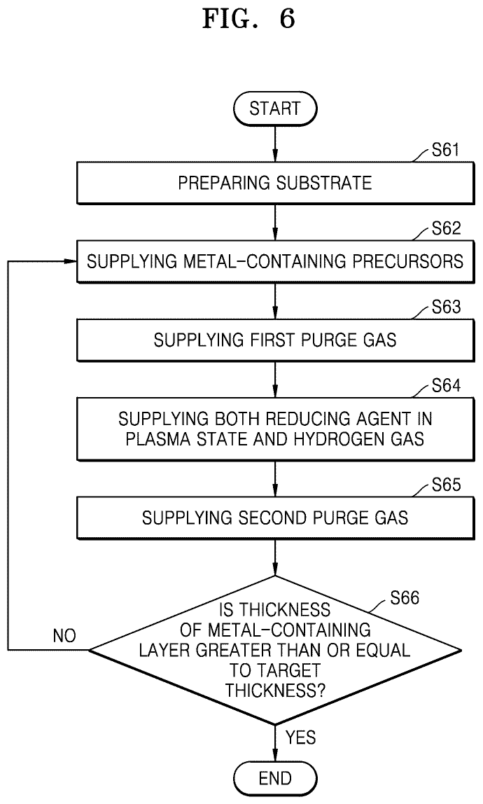

FIG. 6 is a flowchart schematically illustrating a method of manufacturing a semiconductor device, according to embodiments.

Referring to FIG. 6, the method of manufacturing a semiconductor device, according to embodiments, may include operation S61 of preparing a substrate, operation S62 of supplying metal-containing precursors, operation S63 of supplying first purge gas, operation S64 of supplying both a reducing agent in the plasma state and hydrogen gas, operation S65 of supplying second purge gas, and operation S66 of determining whether the thickness of a metal-containing layer is greater than or equal to a target thickness.

Operation S61 of preparing the substrate, operation S62 of supplying the metal-containing precursors, operation S63 of supplying the first purge gas, operation S65 of supplying the second purge gas, and operation S66 of determining whether the thickness of the metal-containing layer is greater than or equal to the target thickness may be the same as operation S11 of preparing the substrate, operation S12 of supplying the metal-containing precursors, operation S13 of supplying the first purge gas, operation S16 of supplying the second purge gas, and operation S17 of determining whether the thickness of the metal-containing layer is greater than or equal to the target thickness in FIG. 1, respectively.

In FIG. 6, operation S64 of supplying both the reducing agent in the plasma state and the hydrogen gas may be performed between operation S63 of supplying the first purge gas and operation S65 of supplying the second purge gas. In this embodiment, both the reducing agent and the hydrogen gas may be supplied in the plasma state.

The reducing agent and the hydrogen gas in the plasma state may be produced using for example, a plasma manufacturing method, such as the DC plasma manufacturing method or the RF plasma manufacturing method, or other plasma manufacturing method known to those skilled in the art. The reducing agent and the hydrogen gas may be produced in the plasma state by arranging two electrodes in a reaction chamber, supplying the reducing agent to the reaction chamber, and then applying a DC current or an AC current to the two electrodes.

In non-limiting examples, operations S62-S65 may be repeated multiple times before operation S66 is performed.

Referring to FIGS. 4 to 6, the reducing agent in the plasma state may be supplied earlier or later than the hydrogen gas. In this embodiment, both the reducing agent and the hydrogen gas may be supplied in the plasma state. For example, an operation of supplying the reducing agent in the plasma state may be freely changed with respect to an operation of supplying the hydrogen gas. Therefore, the degree of process freedom of the method of manufacturing a semiconductor device may increase.

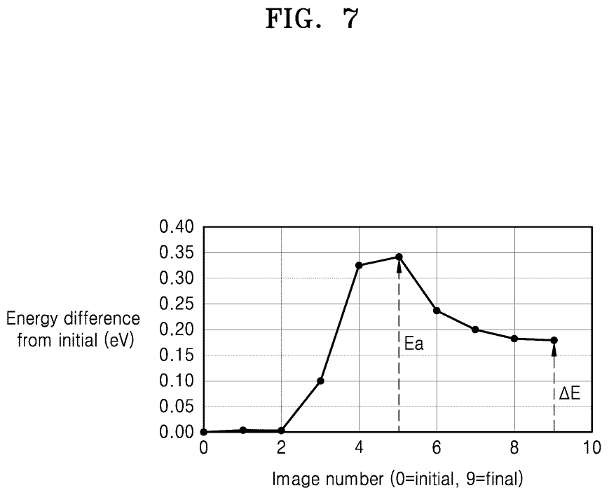

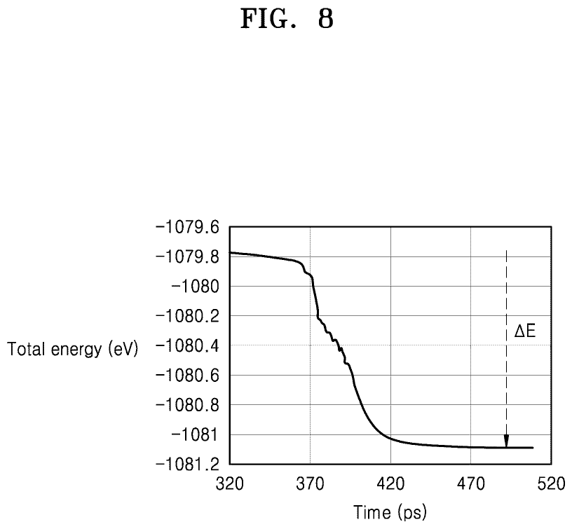

FIGS. 7 and 8 are graphs illustrating results of a comparative example and an experimental example, respectively, according to Vienna ab initio simulation package (VASP) calculation.

FIG. 7 illustrates a graph showing the energy difference from initial (Y axis) of a reaction system according to a reaction progress degree (X axis) of the comparative example. The comparative example corresponds to the reaction of <Formula 3>. The graph of FIG. 7 shows a result of the comparative example according to VSAP calculation. In the graph of FIG. 7, Ea denotes the activation energy of <Formula 3>. Referring to FIG. 7, the activation energy of the comparative example is about 0.34 eV.

In addition, ΔE of FIG. 7 denotes the enthalpy difference between a reactant and a product in the comparative example. ΔE of FIG. 7 may be about 0.18 eV.

FIG. 8 illustrates a graph showing the energy (Y axis) of a reaction system according to a time (X axis) of the experimental example. The experimental example corresponds to the reaction of <Formula 4>. The graph of FIG. 8 shows a result of the experimental example according to VSAP calculation. Unlike FIG. 7, Ea is not shown in the graph of FIG. 8. This indicates that the activation energy of the experimental example is about 0 eV.

In addition, ΔE of FIG. 8 denotes the enthalpy difference between a reactant and a product in the experimental example. ΔE of FIG. 8 may be about 0.65 eV.

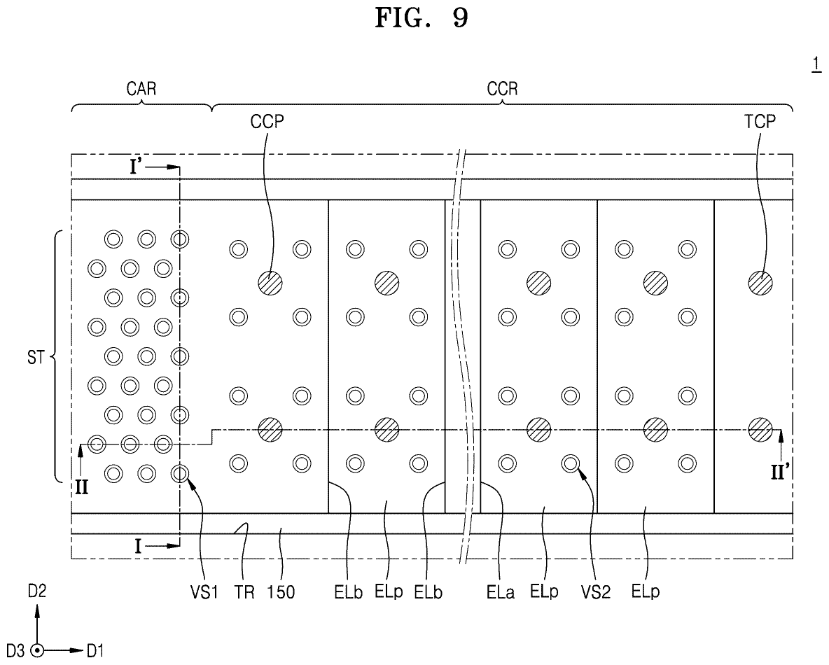

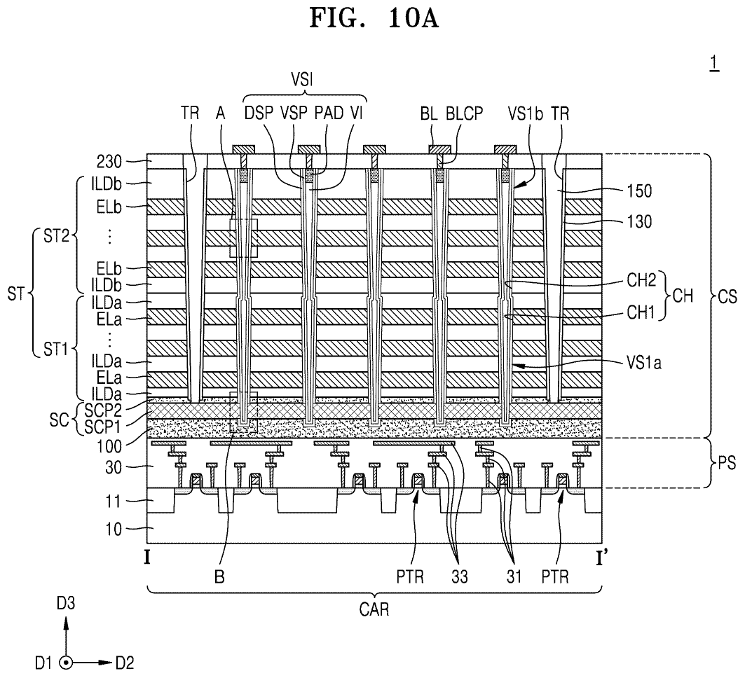

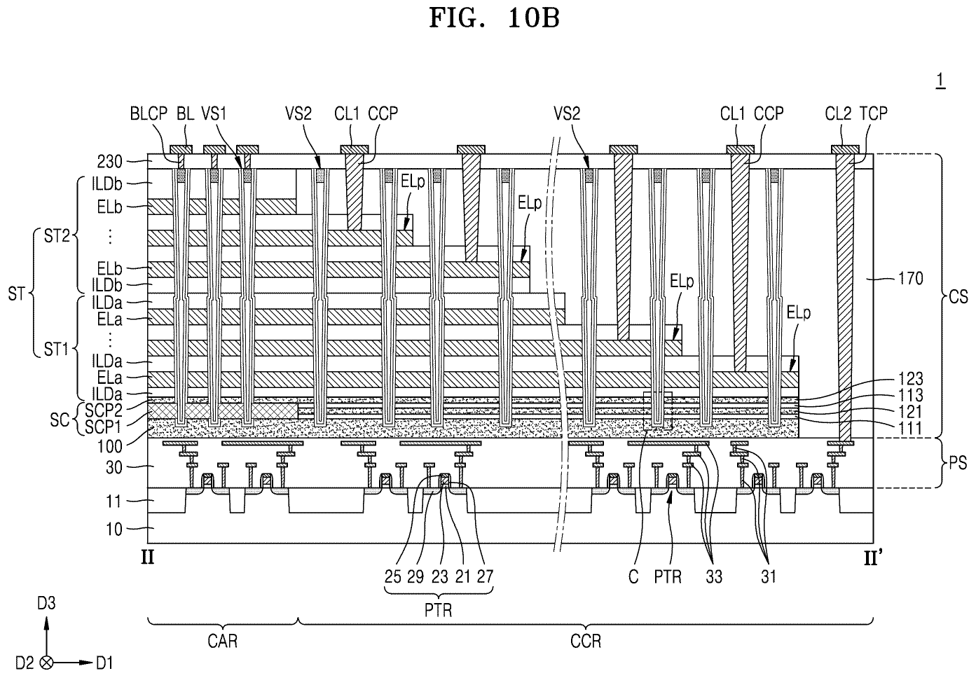

FIG. 9 is a top view illustrating a three-dimensional semiconductor memory device according to embodiments. FIGS. 10A and 10B are cross-sectional views illustrating the three-dimensional semiconductor memory device according to embodiments and respectively correspond to cross-sections cut along lines I-I′ and II-II′ of FIG. 9.

Referring to FIGS. 9, 10A, and 10B, the three-dimensional semiconductor memory device 1 according to the inventive concept may include a first substrate 10, a peripheral circuit structure PS on the first substrate 10, and a cell array structure CS on the peripheral circuit structure PS.

The three-dimensional semiconductor memory device 1 in FIGS. 9, 10A, and 10B may correspond to the semiconductor devices described with reference to FIGS. 1 to 6. For example, the three-dimensional semiconductor memory device 1 may correspond to NAND flash.

The first substrate 10 may include a cell array region CAR and a contact region CCR. The first substrate 10 may extend in a first horizontal direction D1 and a second horizontal direction D2.

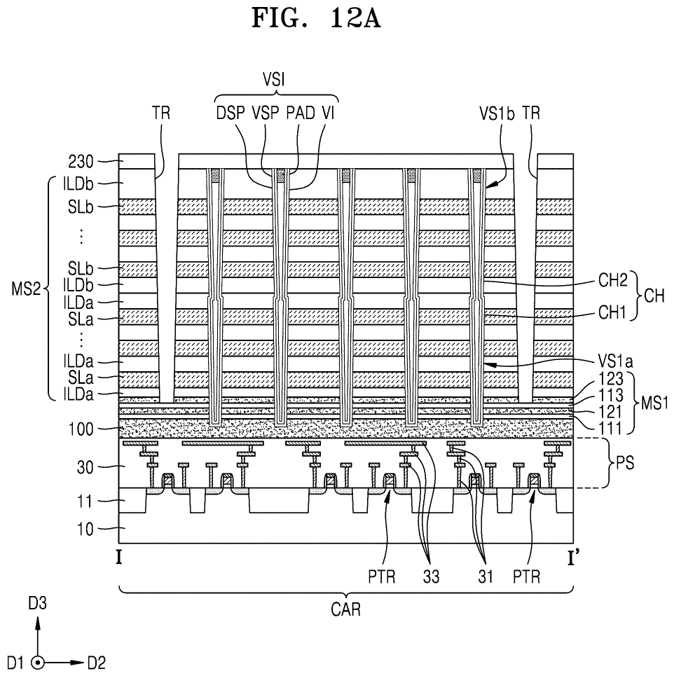

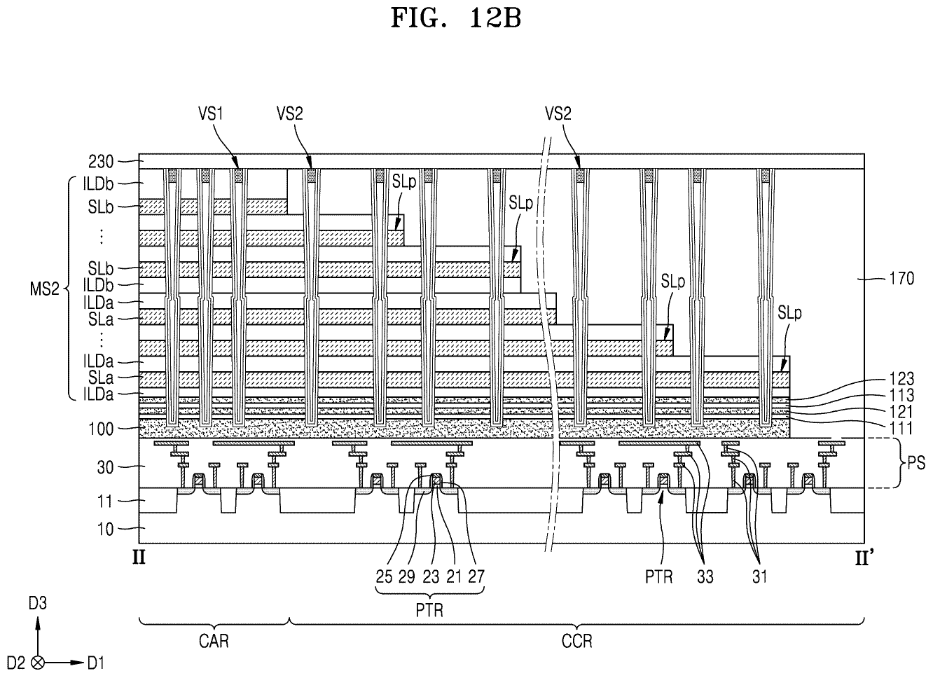

In the present application, the first horizontal direction D1 is defined as one direction parallel to the upper surface of the first substrate 10 (see e.g, FIG. 12A), the second horizontal direction D2 is defined as one direction intersecting the first horizontal direction D1 and parallel to the upper surface of the first substrate 10, and a vertical direction D3 is defined as a direction perpendicular to the upper surface of the first substrate 10. For example, the first horizontal direction D1, the second horizontal direction D2, and the vertical direction D3 may be perpendicular to each other.

The first horizontal direction D1 may be a direction from the cell array region CAR to the contact region CCR.

In a plan view, the contact region CCR may extend in the first horizontal direction D1 (or the opposite direction to the first horizontal direction D1) from the cell array region CAR. The cell array region CAR may be a region in which first and second vertical channel structures VS1 and VS2 and bit lines BL are provided.

The contact region CCR may be a region in which a stepwise structure including pad portions ELp is provided. Unlike FIGS. 9, 10A, and 10B, the contact region CCR may extend in the second horizontal direction D2 (or the opposite direction to the second horizontal direction D2) from the cell array region CAR.

The first substrate 10 may be, for example, a silicon substrate, a silicon-germanium substrate, a germanium substrate, or a monocrystalline epitaxial layer grown on a monocrystalline silicon substrate.

A device isolation layer 11 may be provided inside the first substrate 10. The device isolation layer 11 may define an active region of the first substrate 10. The device isolation layer 11 may include, for example, silicon oxide.

The peripheral circuit structure PS may be on the first substrate 10. The peripheral circuit structure PS may include peripheral circuit transistors PTR on the active region, peripheral contact plugs 31, and peripheral circuit wirings 33 electrically connected to the peripheral circuit transistors PTR via the peripheral contact plugs 31. In addition, the peripheral circuit structure PS may include a first insulating layer 30 surrounding the peripheral circuit transistors PTR, the peripheral contact plugs 31, and the peripheral circuit wirings 33.

As used herein, components described as being “electrically connected” are configured such that an electrical signal can be transferred from one component to the other (although such electrical signal may be attenuated in strength as it is transferred and may be selectively transferred).

The peripheral circuit transistors PTR, the peripheral contact plugs 31, and the peripheral circuit wirings 33 may constitute a peripheral circuit. Each of the peripheral circuit transistors PTR may include a peripheral gate insulating layer 21, a peripheral gate electrode 23, a peripheral capping pattern 25, a peripheral gate spacer 27, and peripheral source/drain regions 29.

The peripheral gate insulating layer 21 may be between the peripheral gate electrode 23 and the first substrate 10. The peripheral capping pattern 25 may be on the peripheral gate electrode 23. The peripheral gate spacer 27 may cover the sidewalls of the peripheral gate insulating layer 21, the peripheral gate electrode 23, and the peripheral capping pattern 25. The peripheral source/drain regions 29 may be inside the first substrate 10 to be adjacent to both sides of the peripheral gate electrode 23.

The peripheral circuit wirings 33 may be electrically connected to the peripheral circuit transistors PTR via the peripheral contact plugs 31. Each of the peripheral circuit transistors PTR may be, for example, an N-type metal oxide semiconductor (NMOS) transistor, a P-type metal oxide semiconductor (PMOS) transistor, or a gate-all-around-type transistor. For example, the peripheral contact plugs 31 may have a width in the first horizontal direction D1 or the second horizontal direction D2, gradually increasing away from the first substrate 10. The peripheral contact plugs 31 and the peripheral circuit wirings 33 may include a conductive material, such as a metal.

The first insulating layer 30 may be on the upper surface of the first substrate 10. The first insulating layer 30 may cover the peripheral circuit transistors PTR, the peripheral contact plugs 31, and the peripheral circuit wirings 33 on the first substrate 10. The first insulating layer 30 may include a plurality of insulating layers having a multi-layer structure. For example, the first insulating layer 30 may include, for example, silicon oxide, silicon nitride, silicon oxynitride, and/or a low dielectric material.

The cell array structure CS including a second substrate 100 and a stacked structure ST on the second substrate 100 may be on the first insulating layer 30. The second substrate 100 may extend in the first horizontal direction D1 and the second horizontal direction D2. The second substrate 100 may not be in a partial region of the contact region CCR.

The second substrate 100 may be a semiconductor substrate including a semiconductor material. The second substrate 100 may include, for example, at least one material selected from the group consisting of silicon, germanium, silicon-germanium, gallium arsenide, indium gallium arsenide, aluminum gallium arsenide, and a mixture thereof.

The stacked structure ST may be on the second substrate 100. The stacked structure ST may extend from the cell array region CAR to the contact region CCR. A plurality of stacked structures ST may be provided and arranged in the second horizontal direction D2. The plurality of stacked structures ST may be spaced apart from each other in the second horizontal direction D2 with an isolation structure 150 therebetween. Hereinafter, for convenience of description, one stacked structure ST is described, but the description herein may also be applied to the other stacked structures ST.

The stacked structure ST may include first and second interlayer insulating layers ILDa and ILDb and first and second gate electrodes ELa and ELb.

For example, the first and second gate electrodes ELa and ELb may correspond to word lines in the three-dimensional semiconductor memory device 1.

More particularly, the stacked structure ST may include a first stacked structure ST1 on the second substrate 100 and a second stacked structure ST2 on the first stacked structure ST1.

The first stacked structure ST1 may include the first interlayer insulating layers ILDa and the first gate electrodes ELa alternately stacked one on another. The second stacked structure ST2 may include the second interlayer insulating layers ILDb and the second gate electrodes ELb alternately stacked one on another.

The respective thicknesses of the first and second gate electrodes ELa and ELb in the vertical direction D3 may be substantially the same as each other. Hereinafter, a thickness means a thickness in the vertical direction D3.

The first and second gate electrodes ELa and ELb may have a length in the first horizontal direction D1, gradually decreasing away from the second substrate 100 (i.e., in the vertical direction D3). In example embodiments, the length of each of the first and second gate electrodes ELa and ELb in the first horizontal direction D1 may be greater than the length of an electrode in the first horizontal direction D1, immediately above a corresponding electrode. The lowermost one of the first gate electrodes ELa of the first stacked structure ST1 may have the greatest length in the first horizontal direction D1, and the uppermost one of the second gate electrodes ELb of the second stacked structure ST2 may have the least length in the first horizontal direction D1.

Each of the first and second gate electrodes ELa and ELb may have a pad portion ELp in the contact region CCR. The pad portions ELp included in the first and second gate electrodes ELa and ELb may be at horizontally and vertically different positions. The pad portions ELp may form a stepwise structure in the first horizontal direction D1.

By the stepwise structure, each of the first and second stacked structures ST1 and ST2 may have a thickness gradually decreasing in the first horizontal direction D1 from the outermost one in the first horizontal direction D1 among the first vertical channel structures VS1. In addition, in a plan view, the sidewalls of the first and second gate electrodes ELa and ELb may be separated by a certain distance in the first horizontal direction D1.

The first and second gate electrodes ELa and ELb may include at least one of, for example, a doped semiconductor (e.g., doped silicon or the like), a metal (e.g., W, copper, aluminum, or the like), conductive metal nitride (e.g., titanium nitride, tantalum nitride, or the like), and a transition metal (e.g., titanium, Ta, or the like).

Alternatively, the first and second gate electrodes ELa and ELb may include Mo. Mo has a low resistance and thus has good thermal conductivity. Because Mo has a high melting point and has stability in a gaseous state, Mo is a material stably operable even at a high temperature. In addition, Mo corresponds to a material having good thermochemical stability, corrosion resistance, and the like and having high solidity. Therefore, when the first and second gate electrodes ELa and ELb include Mo, the electrical characteristics of the three-dimensional semiconductor memory device 1 may be improved.

The first interlayer insulating layers ILDa may be between the first gate electrodes ELa. The second interlayer insulating layers ILDb may be between the second gate electrodes ELb. The sidewall of each of the first interlayer insulating layers ILDa may be aligned with the sidewall of one of the first gate electrodes ELa in contact with the bottom of a corresponding first interlayer insulating layer ILDa, and the sidewall of the second interlayer insulating layers ILDb may be aligned with the sidewall of one of the second gate electrodes ELb in contact with the bottom of a corresponding second interlayer insulating layer ILDb. For example, as with the first and second gate electrodes ELa and ELb, the first and second interlayer insulating layers ILDa and ILDb may have a length in the first horizontal direction D1, gradually decreasing away from the second substrate 100.

The lowermost one of the second interlayer insulating layers ILDb may be in contact with the uppermost one of the first interlayer insulating layers ILDa. For example, the thickness of each of the first and second interlayer insulating layers ILDa and ILDb may be less than the thickness of each of the first and second gate electrodes ELa and ELb. For example, the thickness of the lowermost one of the first interlayer insulating layers ILDa may be less than the thickness of each of the other first and second interlayer insulating layers ILDa and ILDb. For example, the thickness of the uppermost one of the second interlayer insulating layers ILDb may be greater than the thickness of each of the other first and second interlayer insulating layers ILDa and ILDb.

Except for the lowermost one of the first interlayer insulating layers ILDa and the uppermost one of the second interlayer insulating layers ILDb, the respective thicknesses of the other first and second interlayer insulating layers ILDa and ILDb may be substantially the same as each other. However, this is only illustrative, and the thicknesses of the first and second interlayer insulating layers ILDa and ILDb may depend on the characteristics of a semiconductor device.

The first and second interlayer insulating layers ILDa and ILDb may include, for example, at least one material selected from silicon oxide, silicon nitride, silicon oxynitride, and/or a low dielectric material. For example, the first and second interlayer insulating layers ILDa and ILDb may include high density plasma (HDP) oxide or tetraethylorthosilicate (TEOS).

A source structure SC may be between the second substrate 100 and the lowermost one of the first interlayer insulating layers ILDa in the cell array region CAR. The source structure SC may correspond to a common source line (CSL) in the three-dimensional semiconductor memory device 1.

The source structure SC may include a first source conductive pattern SCP1 and a second source conductive pattern SCP2 sequentially stacked on the second substrate 100. The second source conductive pattern SCP2 may be between the first source conductive pattern SCP1 and the lowermost one of the first interlayer insulating layers ILDa. The thickness of the first source conductive pattern SCP1 may be greater than the thickness of the second source conductive pattern SCP2.

The first and second source conductive patterns SCP1 and SCP2 may include a semiconductor material, such as silicon, or an impurity-doped semiconductor material. When the first and second source conductive patterns SCP1 and SCP2 include an impurity-doped semiconductor material, the impurity concentration of the first source conductive pattern SCP1 may be greater than the impurity concentration of the second source conductive pattern SCP2.

The first source conductive pattern SCP1 of the source structure SC may be provided only in the cell array region CAR and may not be provided in the contact region CCR. However, the second source conductive pattern SCP2 of the source structure SC may extend from the cell array region CAR to the contact region CCR. The second source conductive pattern SCP2 in the contact region CCR may be referred to as a second semiconductor layer 123.

A first mold structure MS1 may be between the second substrate 100 and the lowermost one of the first interlayer insulating layers ILDa in the contact region CCR. The first mold structure MS1 may include a first buffer insulating layer 111, a first semiconductor layer 121, a second buffer insulating layer 113, and the second semiconductor layer 123 sequentially stacked on the second substrate 100.

As shown for example, in FIG. 10B, the first semiconductor layer 121 may be between the second substrate 100 and the second semiconductor layer 123. The first buffer insulating layer 111 may be between the second substrate 100 and the first semiconductor layer 121, and the second buffer insulating layer 113 may be between the first semiconductor layer 121 and the second semiconductor layer 123. The lower surface of the first buffer insulating layer 111 may be substantially coplanar with the lower surface of the first source conductive pattern SCP1. The upper surface of the second buffer insulating layer 113 may be substantially coplanar with the upper surface of the first source conductive pattern SCP1.

The first and second buffer insulating layers 111 and 113 may include, for example, silicon oxide. The first and second semiconductor layers 121 and 123 may include a semiconductor material, e.g., silicon.

The first vertical channel structures VS1 penetrating the stacked structure ST and the source structure SC in the cell array region CAR may be provided. The first vertical channel structures VS1 may penetrate at least a portion of the second substrate 100, and the lower surface of each of the first vertical channel structures VS1 may be at a lower level than the upper surface of the second substrate 100 and the lower surface of the source structure SC. For example, the first vertical channel structures VS1 may be in direct contact with the second substrate 100.

In a plan view of FIG. 9, the first vertical channel structures VS1 may be arranged in a zigzag form in the first horizontal direction D1 or the second horizontal direction D2. The first vertical channel structures VS1 may not be provided in the contact region CCR.

The first vertical channel structures VS1 may be provided inside vertical channel holes CH penetrating the stacked structure ST, respectively. Each of the vertical channel holes CH may include a first vertical channel hole CH1 penetrating the first stacked structure ST1 and a second vertical channel hole CH2 penetrating the second stacked structure ST2. The first and second vertical channel holes CH1 and CH2 of each of the vertical channel holes CH may be connected to each other in the vertical direction D3.

It will be understood that when an element is referred to as being “connected” to or “on” another element, it can be directly connected or coupled to or on the other element or intervening elements may be present. In contrast, when an element is referred to as being “directly connected” to another element, or as “contacting” or “in contact with” another element (or using any form of the word “contact”), there are no intervening elements present at the point of contact.

Each of the first vertical channel structures VS1 may include a first portion VS1a and a second portion VS1b. The first portion VS1a may be provided inside the first vertical channel hole CH1, and the second portion VS1b may be provided inside the second vertical channel hole CH2. The second portion VS1b may be provided on and connected to the first portion VS1a.

Each of the first portion VS1a and the second portion VS1b may have a width in the first horizontal direction D1 or the second horizontal direction D2, gradually increasing in the vertical direction D3. The width of the top of the first portion VS1a may be greater than the width of the bottom of the second portion VS1b. In example embodiments, the sidewall of each of the first vertical channel structures VS1 may be stepped at the boundary between the first portion VS1a and the second portion VS1b. However, this is illustrative, the inventive concept is not limited thereto, and the sidewall of each of the first vertical channel structures VS1 may be stepped three or more times at different levels or may be flat without being stepped.

Each of the first vertical channel structures VS1 may include a data storage pattern DSP and a vertical semiconductor pattern VSP sequentially provided on the inner wall of each of the vertical channel holes CH, a buried insulating pattern VI filling an internal space surrounded by the vertical semiconductor pattern VSP, and a conductive pad PAD on the buried insulating pattern VI. The conductive pad PAD may be provided to a space surrounded by the buried insulating pattern VI and the data storage pattern DSP (or the vertical semiconductor pattern VSP).

The upper surface of each of the first vertical channel structures VS1 may have, for example, a circular shape, an oval shape, or a bar shape. The data storage pattern DSP may be adjacent to the stacked structure ST and cover the sidewalls of the first and second interlayer insulating layers ILDa and ILDb and the sidewalls of the first and second gate electrodes ELa and ELb. The vertical semiconductor pattern VSP may conformally cover the inner wall of the data storage pattern DSP.

According to non-limiting examples, the vertical semiconductor pattern VSP may be between the data storage pattern DSP and the buried insulating pattern VI. The vertical semiconductor pattern VSP may have a pipe or macaroni shape with a closed bottom. The data storage pattern DSP may have a pipe or macaroni shape with an opened bottom.

The vertical semiconductor pattern VSP may include, for example, an impurity-doped semiconductor material or an impurity-undoped intrinsic semiconductor material or polycrystalline semiconductor material. The vertical semiconductor pattern VSP may be in contact with a portion of the source structure CS. The conductive pad PAD may include, for example, an impurity-doped semiconductor material or a conductive material.

In the contact region CCR, the second vertical channel structures VS2 penetrating a second insulating layer 170, the stacked structure ST, and the first mold structure MS1 may be provided. More particularly, the second vertical channel structures VS2 may penetrate the pad portions ELp of the first and second gate electrodes ELa and ELb. The second vertical channel structures VS2 may be provided around cell contact plugs CCP described herein. The second vertical channel structures VS2 may not be provided in the cell array region CAR.

The second vertical channel structures VS2 may have substantially the same structure as the first vertical channel structures VS1. However, according to embodiments, the second vertical channel structures VS2 may not be provided.

In the contact region CCR, the second insulating layer 170 covering the stacked structure ST and a portion of the first insulating layer 30 may be provided. More particularly, the second insulating layer 170 may be on the pad portions ELp of the first and second gate electrodes ELa and ELb while covering the stepwise structure of the stacked structure ST. The second insulating layer 170 may have a substantially flat upper surface. The upper surface of the second insulating layer 170 may be substantially coplanar with the top surface of the stacked structure ST. More particularly, the upper surface of the second insulating layer 170 may be substantially coplanar with the upper surface of the uppermost one of the second interlayer insulating layers ILDb of the stacked structure ST.

The second insulating layer 170 may include one or more stacked insulating layers. The second insulating layer 170 may include an insulating material, e.g., silicon oxide, silicon nitride, silicon oxynitride, and/or a low dielectric material. The second insulating layer 170 may include an insulating material different from that of the first and second interlayer insulating layers ILDa and ILDb of the stacked structure ST. For example, when the first and second interlayer insulating layers ILDa and ILDb of the stacked structure ST include HDP oxide, the second insulating layer 170 may include TEOS.

A third insulating layer 230 may be on the uppermost one of the second interlayer insulating layers ILDb. The third insulating layer 230 may cover the upper surface of the uppermost one of the second interlayer insulating layers ILDb. The third insulating layer 230 may cover the upper surfaces of the first and second vertical structures VS1 and VS2. The third insulating layer 230 may include an insulating material, e.g., silicon oxide, silicon nitride, silicon oxynitride, and/or a low dielectric material.

When the plurality of stacked structures ST are provided, the isolation structure 150 may be provided inside a trench TR crossing between every two of the plurality of stacked structures ST in the first horizontal direction D1.

The trench TR may extend from the cell array region CAR of the first substrate 10 to the contact region CCR in the first horizontal direction D1. The isolation structure 150 may be spaced apart from the first and second vertical structures VS1 and VS2 in the second horizontal direction D2.

The upper surface of the isolation structure 150 may be at a higher level than, for example, the upper surfaces of the first and second vertical structures VS1 and VS2. The upper surface of the isolation structure 150 may be coplanar with the upper surface of the third insulating layer 230. For example, the lower surface of the isolation structure 150 may be substantially coplanar with the lower surface of the second source conductive pattern SCP2 and be at a higher level than the upper surface of the second substrate 100.

A plurality of isolation structures 150 may be provided, and the plurality of isolation structures 150 may be spaced apart from each other in the second horizontal direction D2 with the stacked structure ST therebetween.

An isolation spacer 130 may be provided between the isolation structure 150 and the stacked structure ST and surround the isolation structure 150. The isolation spacer 130 may conformally cover the sidewalls of the first and second interlayer insulating layers ILDa and ILDb and the first and second gate electrodes ELa and ELb. The isolation structure 150 and the isolation spacer 130 may include, for example, silicon oxide.

The cell contact plugs CCP may be connected to the first and second gate electrodes ELa and ELb by penetrating the third insulating layer 230 and the second insulating layer 170.

Each of the cell contact plugs CCP may be in direct contact with one of the pad portions ELp of the first and second gate electrodes ELa and ELb by penetrating one of the first and second interlayer insulating layers ILDa and ILDb.

The cell contact plugs CCP may be adjacent to the second vertical channel structures VS2, respectively, and spaced apart from each other.

A peripheral contact plug TCP electrically connected to the peripheral circuit transistors PTR of the peripheral circuit structure PS by penetrating the third insulating layer 230 and the second insulating layer 170 may be provided. Like shown in FIG. 9, a plurality of peripheral contact plugs TCP may be provided. The peripheral contact plug TCP may be spaced apart from the second substrate 100, the source structure SC, and the stacked structure ST in the first horizontal direction D1.

Each of the cell contact plugs CCP and the peripheral contact plug TCP may include a conductive pattern including, for example, at least one metal selected from the group consisting of aluminum, copper, W, Mo, and cobalt, and a barrier pattern including a metal layer/metal nitride layer. The metal layer may include, for example, at least one of titanium, Ta, W, nickel, cobalt, and platinum. The metal nitride layer may include, for example, at least one of titanium nitride (TiN), tantalum nitride (TaN), tungsten nitride (WN), nickel nitride (NiN), cobalt nitride (CoN), and platinum nitride (PtN).

A bit line contact plug BLCP connected to a first vertical channel structure VS1 by penetrating the third insulating layer 230 may be provided. The bit line contact plug BLCP may be electrically connected to the first vertical channel structure VS1. A plurality of bit line contact plugs BLCP may be provided.

The plurality of bit line contact plugs BLCP, the cell contact plugs CCP, and the peripheral contact plug TCP may have a width in the first horizontal direction D1 or the second horizontal direction D2, gradually increasing in the vertical direction D3.

A bit line BL connected to the bit line contact plug BLCP may be on the third insulating layer 230. A plurality of bit lines BL may be provided.

A first conductive line CL1 connected to a cell contact plug CCP and a second conductive line CL2 connected to the peripheral contact plug TCP may be on the third insulating layer 230. A plurality of first conductive lines CL1 and a plurality of second conductive lines CL2 may be provided.

The bit line contact plug BLCP, the cell contact plug CCP, the peripheral contact plug TCP, the bit line BL, the first conductive line CL1, and the second conductive line CL2 may include a conductive material, e.g., a metal. Although not shown in FIGS. 10A and 10B, additional wirings and additional vias electrically connected to the plurality of bit lines BL and the first and second conductive lines CL1 and CL2 may be further provided on the third insulating layer 230.

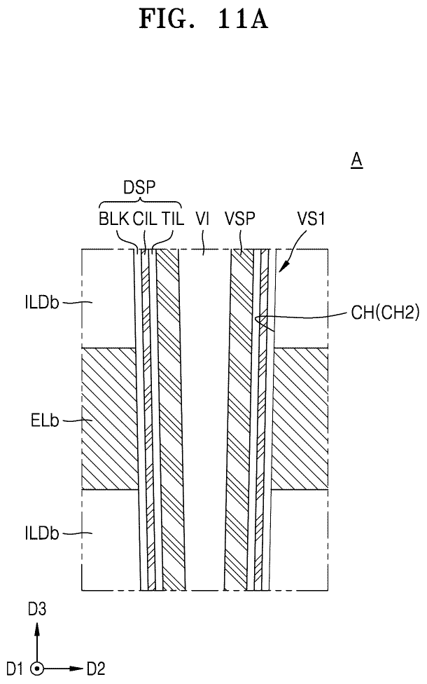

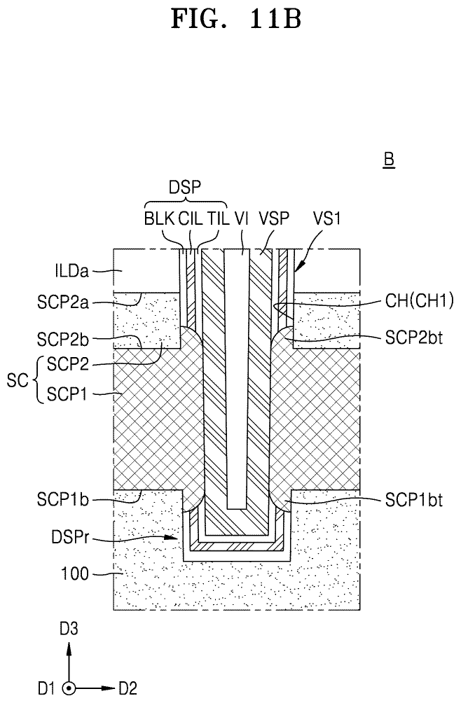

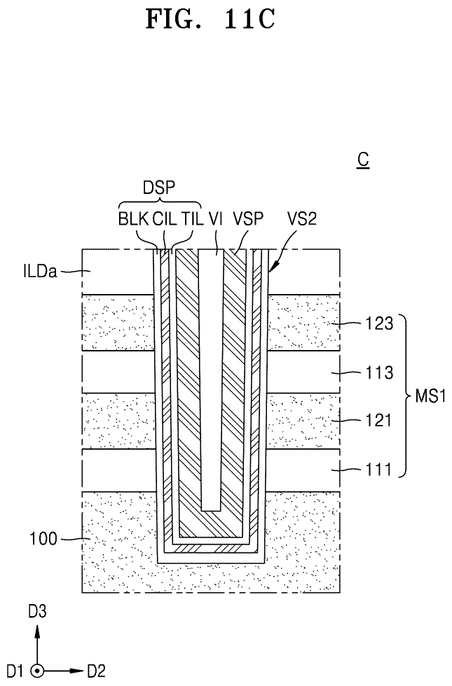

FIG. 11A is a magnified view illustrating a portion of a three-dimensional semiconductor memory device according to embodiments and corresponds to a portion A of FIG. 10A. FIG. 11B is a magnified view illustrating a portion of a three-dimensional semiconductor memory device according to embodiments and corresponds to a portion B of FIG. 10A.

Referring to FIGS. 10A, 11A, and 11B, one of the first vertical channel structures VS1, including the source structure SC including the first and second source conductive patterns SCP1 and SCP2, the data storage pattern DSP, the vertical semiconductor pattern VSP, the buried insulating pattern VI, and a lower data storage pattern DSPr, is shown.

Hereinafter, for convenience of description, one stacked structure ST and one first vertical channel structure VS1 are described, but the description herein may also be applied to the other first vertical channel structures VS1 penetrating the other stacked structures ST.

The data storage pattern DSP may include, for example, a blocking insulating layer BLK, a charge storage layer CIL, and a tunneling insulating layer TIL that are sequentially stacked. The blocking insulating layer BLK may be adjacent to the stacked structure ST, and the tunneling insulating layer TIL may be adjacent to the vertical semiconductor pattern VSP. The charge storage layer CIL may be between the blocking insulating layer BLK and the tunneling insulating layer TIL. The blocking insulating layer BLK may conformally cover the inner wall of each of the vertical channel holes CH.

Between the first and second gate electrodes ELa and ELb and the vertical semiconductor pattern VSP and between the first and second interlayer insulating layers ILDa and ILDb and the vertical semiconductor pattern VSP, the blocking insulating layer BLK, the charge storage layer CIL, and the tunneling insulating layer TIL may extend in the vertical direction D3.

By a Fowler-Nordheim tunneling effect induced by the voltage difference between the vertical semiconductor pattern VSP and the first and second gate electrodes ELa and ELb, the data storage pattern DSP may store and/or update data. For example, the blocking insulating layer BLK and the tunneling insulating layer TIL may include silicon oxide, and the charge storage layer CIL may include silicon nitride or silicon oxynitride.

The first source conductive pattern SCP1 of the source structure SC may be in contact with the vertical semiconductor pattern VSP, and the second source conductive pattern SCP2 thereof may be spaced apart from the vertical semiconductor pattern VSP with the data storage pattern DSP therebetween. The first source conductive pattern SCP1 may be spaced apart from the buried insulating pattern VI with the vertical semiconductor pattern VSP therebetween.

More particularly, the first source conductive pattern SCP1 may include protrusion portions SCP1bt at a higher level than a lower surface SCP2b of the second source conductive pattern SCP2 or at a lower level than a lower surface SCP1b of the first source conductive pattern SCP1. However, the protrusion portions SCP1bt may be at a lower level than an upper surface SCP2a of the second source conductive pattern SCP2. In the protrusion portions SCP1bt, for example, a surface in contact with the data storage pattern DSP or the lower data storage pattern DSPr may have a curved shape.

FIG. 11C is a magnified view illustrating a portion of a three-dimensional semiconductor memory device according to example embodiments and corresponds to a portion C of FIG. 10B.

Referring to FIGS. 10B and 11C, one of the second vertical channel structures VS2, including the data storage pattern DSP, the vertical semiconductor pattern VSP, and the buried insulating pattern VI, and the first mold structure MS1 including the first and second buffer insulating layers 111 and 113 and the first and second semiconductor layers 121 and 123, are shown.

In example embodiments, the first and second buffer insulating layers 111 and 113, the first and second semiconductor layers 121 and 123, and the second substrate 100 may not be in contact with the vertical semiconductor pattern VSP of each of the second vertical channel structures VS2.

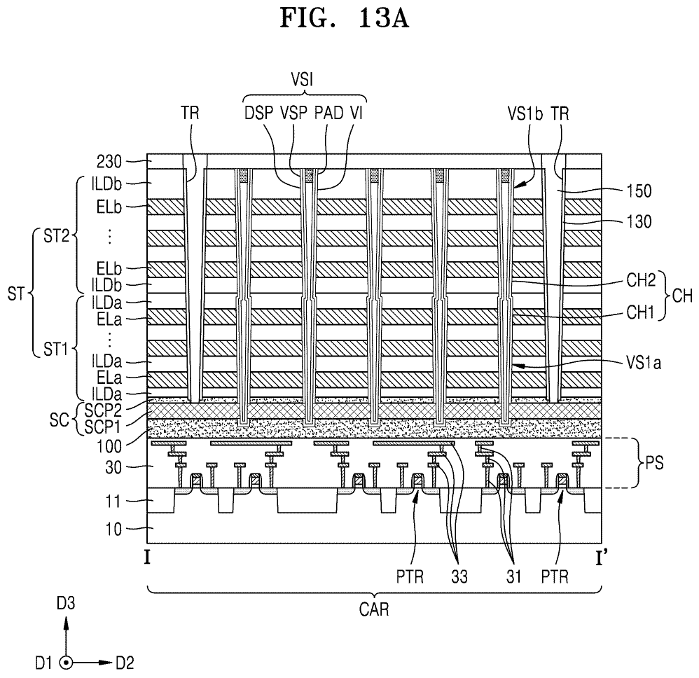

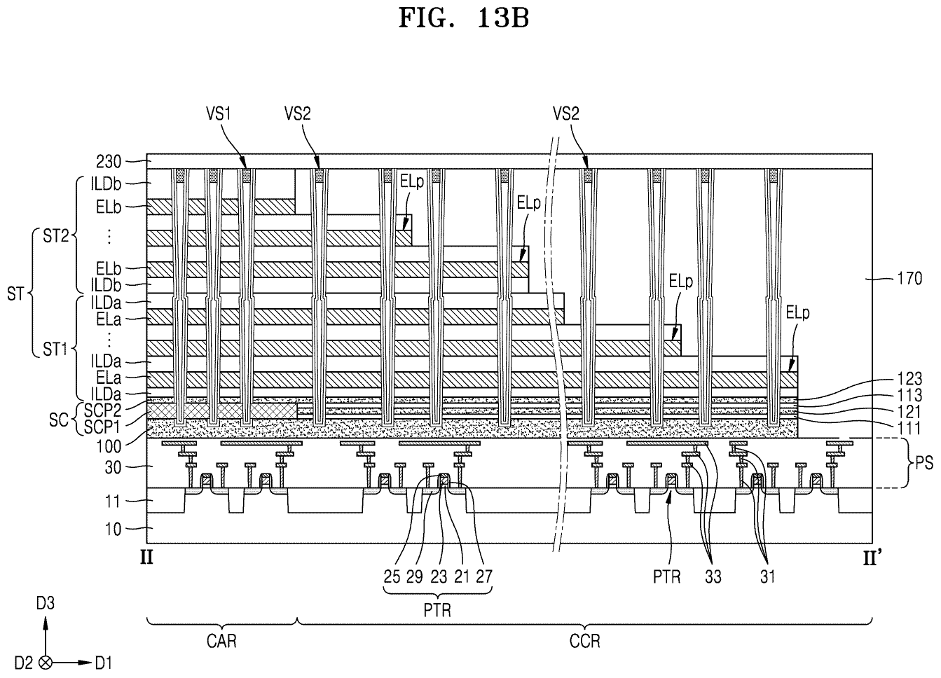

FIGS. 12A to 13B are cross-sectional views illustrating a method of manufacturing a three-dimensional semiconductor memory device, according to embodiments, and particularly, FIGS. 12A and 13A correspond to cross-sections cut along line I-I′ of FIG. 9, and FIGS. 12B and 13B correspond to cross-sections cut along line II-II′ of FIG. 9. Hereinafter, the method of manufacturing a three-dimensional semiconductor memory device, according to embodiments, is described in detail with reference to FIGS. 12A to 13B, 9, 10A, and 10B.

Referring to FIGS. 9, 12A, and 12B, the first substrate 10 including the cell array region CAR and the contact region CCR may be provided. The device isolation layer 11 defining an active region may be formed in the first substrate 10. The device isolation layer 11 may be formed by forming a trench at an upper portion of the first substrate 10 and filling the trench with silicon oxide.

The peripheral circuit transistors PTR may be formed on the active region defined by the device isolation layer 11. The peripheral contact plugs 31 and the peripheral circuit wirings 33 connected to the peripheral source/drain regions 29 of the peripheral circuit transistors PTR may be formed. The first insulating layer 30 covering the peripheral circuit transistors PTR, the peripheral contact plugs 31, and the peripheral circuit wirings 33 may be formed.

The second substrate 100 may be formed on the first insulating layer 30. The second substrate 100 may extend from the cell array region CAR to the contact region CCR.

A portion of the second substrate 100 in the contact region CCR may be removed. The removing of the portion of the second substrate 100 may be performed by forming a mask pattern covering a portion of the contact region CCR and the cell array region CAR and by patterning the second substrate 100 through the mask pattern. The removing of the portion of the second substrate 100 may include making a space in which the peripheral contact plug TCP is to be provided.

The first mold structure MS1 may be formed on the second substrate 100. The forming of the first mold structure MS1 may include sequentially stacking the first buffer insulating layer 111, the first semiconductor layer 121, the second buffer insulating layer 113, and the second semiconductor layer 123 on the second substrate 100. The term “sequential stacking”, relates to the positioning of the layers with respect to one another and is not intended to imply a limitation on the timing and order of stacking the layers on one another.

The first and second buffer insulating layers 111 and 113 may be formed of, for example, silicon oxide. The first and second semiconductor layers 121 and 123 may be formed of a semiconductor material, e.g., silicon.

A second mold structure MS2 may be formed on the first mold structure MS1. The forming of the second mold structure MS2 may include alternately stacking the first interlayer insulating layers ILDa and first sacrificial layers SLa on the second substrate 100, forming first vertical channel holes CH1 penetrating the first interlayer insulating layers ILDa and the first sacrificial layers SLa, forming first channel sacrificial patterns respectively filling the first vertical channel holes CH1, alternately stacking the second interlayer insulating layers ILDb and second sacrificial layers SLb on the uppermost one of the first interlayer insulating layers ILDa, forming second vertical channel holes CH2 penetrating the second interlayer insulating layers ILDb and the second sacrificial layers SLb and respectively connected to the first vertical channel holes CH1, and forming second channel sacrificial patterns respectively filling the second vertical channel holes CH2 and respectively connected to the first channel sacrificial patterns.

The first vertical channel holes CH1 may penetrate not only the first interlayer insulating layers ILDa and the first sacrificial layers SLa but also the first mold structure MS1 and further penetrate at least a portion of the second substrate 100.

Before the forming of the first vertical channel holes CH1 and the forming of the second vertical channel holes CH2, a trimming process may be performed on the second mold structure MS2 in the contact region CCR.

The trimming process may include forming a mask pattern covering a portion of the upper surface of the second mold structure MS2 in the cell array region CAR and the contact region CCR, patterning the second mold structure MS2 through the mask pattern, reducing the area of the mask pattern, and patterning the second mold structure MS2 through the mask pattern having the reduced area.

The reducing of the area of the mask pattern and the patterning of the second mold structure MS2 through the mask pattern may be repeated in turn. By the trimming process, the second mold structure MS2 may have a stepwise structure. By the trimming process, each of the first and second sacrificial layers SLa and SLb may have a preliminary pad portion SLp.

Alternatively, the trimming process may be performed after forming the first vertical channel holes CH1. This may depend on a design of a three-dimensional semiconductor memory device to be manufactured.

The first and second sacrificial layers SLa and SLb may be formed of an insulating material that is different from the insulating material of the first and second interlayer insulating layers ILDa and ILDb. The first and second sacrificial layers SLa and SLb may be formed a material having etch selectivity with respect to the first and second interlayer insulating layers ILDa and ILDb. For example, the first and second sacrificial layers SLa and SLb may be formed of silicon nitride, and the first and second interlayer insulating layers ILDa and ILDb may be formed of silicon oxide. The first and second sacrificial layers SLa and SLb may be formed with a substantially the same thickness, and the first and second interlayer insulating layers ILDa and ILDb may have different thicknesses in some regions.

The second insulating layer 170 may be formed. The second insulating layer 170 may surround a side surface of the second mold structure MS2. The second insulating layer 170 may cover the preliminary pad portions SL. The second insulating layer 170 may have a single-layer or multi-layer structure.

The second channel sacrificial patterns and the first channel sacrificial patterns may be removed. In the cell array region CAR, the first vertical channel structures VS1 filling spaces (i.e., the vertical channel holes CH) from which the first and second channel sacrificial patterns have been removed may be formed. Likewise, in the contact region CCR, the second vertical channel structures VS2 respectively filling the vertical channel holes CH may be formed.

The forming of each of the first and second vertical structures VS1 and VS2 may include forming the data storage pattern DSP conformally covering the inner wall of each of the vertical channel holes CH, forming the vertical semiconductor pattern VSP conformally covering the sidewall of the data storage pattern DSP, forming the buried insulating pattern VI filling at least a portion of a space surrounded by the vertical semiconductor pattern VSP, and forming the conductive pad PAD filling a space surrounded by the vertical semiconductor pattern VSP and the buried insulating pattern VI.

The third insulating layer 230 covering the upper surfaces of the first and second vertical structures VS1 and VS2 and the upper surface of the uppermost one of the second interlayer insulating layers ILDb may be formed.

The trench TR penetrating the third insulating layer 230 and the second mold structure MS2 may be formed. The trench TR may further penetrate at least a portion of the first mold structure MS1. The bottom surface of the trench TR may be at a lower level than the lower surface of the second mold structure MS2 (i.e., the lower surface of the lowermost one of the first interlayer insulating layers ILDa) and the upper surface of the first mold structure MS1. Particularly, the bottom surface of the trench TR may be lower than the upper surface of the first semiconductor layer 121 and higher than the lower surface of the first semiconductor layer 121. By the trench TR, the sidewalls of the first and second interlayer insulating layers ILDa and ILDb and the sidewalls of the first and second sacrificial layers SLa and SLb may be exposed. The trench TR may extend from the cell array region CAR to the contact region CCR.

Although not shown in FIG. 12A, a preliminary spacer covering a portion of the inner wall of the trench TR may be formed. The preliminary spacer may cover the sidewalls of the first and second sacrificial layers SLa and SLb, the sidewalls of the first and second interlayer insulating layers ILDa and ILDb, and the sidewall of the second semiconductor layer 123. The preliminary spacer may include a material having etch selectivity with respect to the first and second semiconductor layers 121 and 123 and the first and second buffer insulating layers 111 and 113. The preliminary spacer may include, for example, silicon nitride.

Referring to FIGS. 9, 13A, and 13B, the first semiconductor layer 121 exposed by the trench TR and the preliminary spacer may be selectively removed. The selective removal of the first semiconductor layer 121 may be performed through a wet etching process using an etching solution. The first semiconductor layer 121 may be selectively removed to expose the first and second buffer insulating layers 111 and 113.

The first and second buffer insulating layers 111 and 113 may be selectively removed. The selective removal of the first and second buffer insulating layers 111 and 113 may be performed for example, through a wet etching process using an etching solution. When the first and second buffer insulating layers 111 and 113 are selectively removed, a portion of the data storage pattern DSP of each of the first vertical channel structures VS1 may be removed. By doing this, a portion of the vertical semiconductor pattern VSP of each of the first vertical channel structures VS1 may be exposed.

The removal of the first and second buffer insulating layers 111 and 113 may be performed in the cell array region CAR, and the first mold structure MS1 in the contact region CCR (in particular, a portion of each of the first and second buffer insulating layers 111 and 113 provided in the contact region CCR) may remain as it is.

The first source conductive pattern SCP1 filling a space from which the first semiconductor layer 121, the first and second buffer insulating layers 111 and 113, and the portion of the data storage pattern DSP of each of the first vertical channel structures VS1 have been removed, may be formed. Although not shown in FIGS. 13A and 13B, air gaps may be formed inside the first source conductive pattern SCP1. The second semiconductor layer 123 in the cell array region CAR may be referred to as the second source conductive pattern SCP2, and as a result, the source structure SC including the first and second source conductive patterns SCP1 and SCP2 may be formed.

The preliminary spacer may be removed, and the sidewalls of the first and second interlayer insulating layers ILDa and ILDb and the sidewalls of the first and second sacrificial layers SLa and SLb may be exposed again. The first and second sacrificial layers SLa and SLb exposed by the trench TR may be selectively removed. The selective removal of the first and second sacrificial layers SLa and SLb may be performed through a wet etching process using an etching solution.

The first and second gate electrodes ELa and ELb respectively filling spaces from which the first and second sacrificial layers SLa and SLb have been removed may be formed. Each of the first and second gate electrodes ELa and ELb may include the pad portion ELp.

An example method of forming the first and second gate electrodes ELa and ELb may use at least any one of the methods of manufacturing a semiconductor, which have been described with reference to FIGS. 1 to 6.

The first and second gate electrodes ELa and ELb may include, for example, Mo. The first and second gate electrodes ELa and ELb may correspond to the metal-containing layer in FIGS. 1 to 6.

When using at least any one of the methods of manufacturing a semiconductor, which have been described with reference to FIGS. 1 to 6, a time taken to form the first and second gate electrodes ELa and ELb may be dramatically reduced. In example embodiments, a time taken to form the metal-containing layer may be dramatically reduced. Therefore, the manufacturing speed of the three-dimensional semiconductor memory device 1 may be dramatically improved by the present methods.

In addition, when using at least any one of the methods of manufacturing a semiconductor, which have been described with reference to FIGS. 1 to 6, oxygen impurities included in the first and second gate electrodes ELa and ELb may be effectively removed. In example embodiments, oxygen impurities included in the metal-containing layer may be effectively removed. Therefore, the electrical characteristics of the first and second gate electrodes ELa and ELb and the three-dimensional semiconductor memory device 1 may be improved.

Accordingly, at least because of the improved characteristics of the metal, described herein, containing layer produced by the present methods, the present invention is also directed to semiconductor devices produced by the present methods.

After forming the first and second gate electrodes ELa and ELb, the isolation spacer 130 and the isolation structure 150 filling the trench TR may be formed. The upper surface of the isolation structure 150 may be substantially coplanar with the upper surface of the third insulating layer 230. As a result, the stacked structure ST including the first and second gate electrodes ELa and ELb and the first and second interlayer insulating layers ILDa and ILDb may be formed.

Referring to FIGS. 9, 10A, and 10B, the cell contact plug CCP connected to the pad portion ELp of each of the first and second gate electrodes ELa and ELb may be formed. The cell contact plug CCP may penetrate the third insulating layer 230 and the second insulating layer 170. The cell contact plug CCP may further penetrate any one of the first and second interlayer insulating layers ILDa and ILDb.

The peripheral contact plug TCP, electrically connected to the peripheral circuit transistors PTR of the peripheral circuit structure PS by penetrating the third insulating layer 230 and the second insulating layer 170, may be formed. The peripheral contact plug TCP may be spaced apart from the second substrate 100, the source structure SC, and the stacked structure ST in the first horizontal direction D1.

The bit line contact plug BLCP connected to the first vertical channel structure VS1 by penetrating the third insulating layer 230 may be formed.

The bit line BL connected to the bit line contact plug BLCP may be formed on the third insulating layer 230. The first conductive line CL1 connected to the cell contact plug CCP may be formed on the third insulating layer 230. The second conductive line CL2 connected to the peripheral contact plug TCP may be formed on the third insulating layer 230. Finally, the three-dimensional semiconductor memory device 1 may be manufactured.

While the inventive concept has been particularly shown and described with reference to embodiments thereof, it will be understood that various changes in form and details may be made herein without departing from the spirit and scope of the present invention.

What is claimed is:

1. A method of manufacturing a semiconductor device, the method comprising:
preparing a substrate;
supplying metal-containing precursors onto the substrate to form a substrate having metal-containing precursors thereon;
supplying hydrogen gas onto the substrate having the metal-containing precursors thereon; and
supplying a reducing agent onto the substrate having the metal-containing precursors thereon,
wherein the supplying of the reducing agent and the supplying of the hydrogen gas are simultaneously or sequentially performed,
wherein the metal-containing precursors comprise molybdenum dichloride dioxide (MoO₂Cl₂), and the reducing agent comprises a hydrogen halide.

2. The method of claim 1, wherein the supplying of the reducing agent comprises supplying the reducing agent in a plasma state.

3. The method of claim 1, wherein the supplying of the hydrogen gas comprises supplying the hydrogen gas in a plasma state.

4. The method of claim 1, further comprising, after the supplying of the metal-containing precursors and before the supplying of the hydrogen gas and the supplying of the reducing agent, supplying first purge gas onto the substrate having the metal-containing precursors thereon.

5. The method of claim 4, further comprising, after the supplying of the hydrogen gas and the supplying of the reducing agent, supplying second purge gas onto the substrate to which the hydrogen gas and the reducing agent have been supplied.

6. The method of claim 1, further comprising, after preparing the substrate and before the supplying the metal-containing precursors, forming a metal nitride layer on the substrate.

7. The method of claim 1, wherein, in the supplying of the reducing agent, a temperature of a reaction chamber in which the supplying of the reducing agent is performed is 300° C. to 800° C.

8. The method of claim 1, wherein, in the supplying of the reducing agent, pressure of a reaction chamber in which the supplying of the reducing agent is performed is 0.1 Torr to 100 Torr and a flow rate of the reducing agent is 100 sccm to 100000 sccm.

9. The method of claim 1, wherein a metal-containing layer is formed on the substrate through the supplying of the metal-containing precursors, the supplying of the hydrogen gas, and the supplying of the reducing agent, and
wherein the supplying of the metal-containing precursors, the supplying of the hydrogen gas, and the supplying of the reducing agent are repeated until a thickness of the metal-containing layer reaches a set target thickness.

10. The method of claim 1, wherein the supplying of the reducing agent and the supplying of the hydrogen gas are sequentially performed.

11. The method of claim 1, wherein the supplying of the reducing agent and the supplying of the hydrogen gas are simultaneously performed.

12. A method of manufacturing a semiconductor device, the method comprising:
forming a mold structure on a substrate, the mold structure comprising sacrificial layers and interlayer insulating layers alternately stacked one on another;
forming vertical channel structures penetrating the mold structure;
forming trenches spaced apart from the vertical channel structures in a horizontal direction and penetrating the mold structure;
selectively removing the sacrificial layers through the trenches;
forming gate electrodes in spaces from which the sacrificial layers have been removed; and
forming an isolation structure filling the trenches,
wherein the forming of the gate electrodes comprises:
supplying metal-containing precursors onto the substrate to form a substrate having metal containing precursors thereon;
supplying hydrogen gas onto the substrate having metal-containing precursors thereon; and
supplying a reducing agent onto the substrate having metal-containing precursors thereon,
wherein the supplying of the reducing agent and the supplying of the hydrogen gas are simultaneously or sequentially performed,
wherein the metal-containing precursors comprise molybdenum dichloride dioxide (MoO₂Cl₂), and the reducing agent comprises a hydrogen halide.

13. The method of claim 12, wherein the supplying of the reducing agent comprises supplying the reducing agent in a plasma state.

14. The method of claim 12, wherein the supplying of the hydrogen gas comprises supplying the hydrogen gas in a plasma state.

15. The method of claim 12, wherein, after the supplying of the metal-containing precursors and before the supplying of the hydrogen gas and the supplying of the reducing agent, supplying first purge gas onto the substrate having metal-containing precursors thereon.

16. The method of claim 15, wherein, after the supplying of the hydrogen gas and the supplying of the reducing agent, supplying second purge gas onto the substrate to which the hydrogen gas and the reducing agent have been supplied.

17. The method of claim 12, wherein, in the supplying of the reducing agent, a temperature of a reaction chamber in which the supplying of the reducing agent is performed is 300° C. to 800° C.

18. The method of claim 12, wherein a metal-containing layer is formed on the substrate through the supplying of the metal-containing precursors, the supplying of the hydrogen gas, and the supplying of the reducing agent, and the supplying of the metal-containing precursors, the supplying of the hydrogen gas, and the supplying of the reducing agent are repeated until a thickness of the metal-containing layer reaches a set target thickness.

19. The method of claim 12, wherein the supplying of the reducing agent and the supplying of the hydrogen gas are simultaneously performed.

20. A method of manufacturing a semiconductor device, the method comprising:
preparing a substrate;
supplying metal-containing precursors onto the substrate, the metal-containing precursors comprising molybdenum dichloride dioxide (MoO₂Cl₂), to form a substrate having metal-containing precursors thereon;
supplying a first purge gas onto the substrate to which the metal-containing precursors have been supplied, the first purge gas comprising a first inert gas;
simultaneously or sequentially supplying hydrogen gas and a reducing agent onto the substrate to which the metal-containing precursors have been supplied, the reducing agent comprising a hydrogen halide;
supplying second purge gas onto the substrate to which the hydrogen gas and the reducing agent have been supplied, the second purge gas comprising a second inert gas; and
checking whether a thickness of a metal-containing layer formed after supplying the second purge gas has reached a set target thickness,
wherein, in the supplying of the hydrogen gas and the supplying of the reducing agent, the hydrogen gas and the reducing agent are supplied in a plasma state.
